(19) United States
(12) Patent Application Publication
(10) Pub. No.: US 2024/0121950 A1
(43) Pub. Date: Apr. 11, 2024

(54) SEMICONDUCTOR DEVICE

(71) Applicant: Samsung Electronics Co., Ltd., Suwon-si (KR)

(72) Inventors: Jaecheon YONG, Suwon-si (KR); Daehong KO, Seoul (KR)

(73) Assignees: Samsung Electronics Co., Ltd., Suwon-si (KR); UIF (University Industry Foundation), Yonsei University, Seoul (KR)

(21) Appl. No.: 18/472,904

(22) Filed: Sep. 22, 2023

(30) Foreign Application Priority Data
Oct. 6, 2022 (KR) 10-2022-0127933

(51) Int. Cl. H10B 12/00

(52) U.S. Cl. CPC H10B 12/488; H10B 12/31; H10B 12/482

(57) ABSTRACT

A semiconductor device includes a substrate, a plurality of semiconductor patterns spaced apart from each other in a first horizontal direction on the substrate, where each of the plurality of semiconductor patterns has first side surfaces opposing each other in the first horizontal direction and second side surfaces opposing each other in a second horizontal direction, the first and second horizontal directions parallel to an upper surface of the substrate, the second horizontal direction perpendicular to the first horizontal direction, source/drain regions on the second side surfaces of each of the plurality of semiconductor patterns, a plurality of gate patterns surrounding upper surfaces, lower surfaces, and the first side surfaces of each of the plurality of semiconductor patterns, a plurality of conductive line patterns connecting the plurality of gate patterns to each other, and data storage structures in parallel to the plurality of semiconductor patterns in the second horizontal direction.

### CROSS-REFERENCE TO RELATED APPLICATION

This application claims benefit of priority to Korean Patent Application No. 10-2022-0127933 filed on Oct. 6, 2022 in the Korean Intellectual Property Office, the disclosure of which is incorporated herein by reference in its entirety.

### BACKGROUND

Example embodiments of the present inventive concepts relate to semiconductor devices.

According to development of the electronic industry and user demand, electronic devices have been designed to have a more compact size and higher degrees of performance. Accordingly, semiconductor devices used in electronic devices have been required to have high integration density and high performance. Since integration density of a general two-dimensional or planar semiconductor device may be mainly determined by the region occupied by a unit memory cell, integration density may be greatly affected by the level of technique of forming a fine pattern. However, since ultra-expensive devices are required for reducing the pattern, integration density of 2D semiconductor devices has been increased but there may be limitations. Accordingly, three-dimensional semiconductor memory devices having three-dimensionally arranged memory cells have been suggested.

### SUMMARY

Some example embodiments of the present inventive concepts provide a semiconductor device having improved electrical properties and integration density.

According to some example embodiments of the present inventive concepts, a semiconductor device may include a substrate and a plurality of semiconductor patterns spaced apart from each other in a first horizontal direction on the substrate, where each of the plurality of semiconductor patterns has first side surfaces opposing each other in the first horizontal direction and second side surfaces opposing each other in a second horizontal direction, where the first horizontal direction is parallel to an upper surface of the substrate and the second horizontal direction is parallel to the upper surface of the substrate and perpendicular to the first horizontal direction. The semiconductor device may further include source/drain regions on the second side surfaces of each of the plurality of semiconductor patterns, a plurality of gate patterns surrounding an upper surface, a lower surface, and the first side surfaces of each of the plurality of semiconductor patterns, a plurality of conductive line patterns connecting the plurality of gate patterns to each other, and data storage structures in parallel to the plurality of semiconductor patterns in the second horizontal direction.

According to some example embodiments of the present inventive concepts, a semiconductor device may include a substrate, a plurality of horizontal structures and a plurality of interlayer insulating layers alternately stacked on the substrate, and a vertical conductive pattern extending in a vertical direction perpendicular to an upper surface of the substrate on the substrate. Each of the plurality of horizontal structures may include a first structure on a first side of the vertical conductive pattern and a second structure spaced apart from the first structure and on a second side of the vertical conductive pattern opposing the first side. The vertical conductive pattern may be electrically connected to the first structure and the second structure of each of the plurality of horizontal structures between the first structure and the second structure. Each of the first structure and the second structure may include a semiconductor pattern having first side surfaces opposing each other in a first horizontal direction and second side surfaces opposing each other in a second horizontal direction, where the first horizontal direction is parallel to the upper surface of the substrate and the second horizontal direction is parallel to the upper surface of the substrate and perpendicular to the first horizontal direction, source/drain regions including a first source/drain region disposed on one side of the second side surfaces of the semiconductor pattern, and a second source/drain region disposed on an opposite side opposing the one side of the second side surfaces of the semiconductor pattern and between the semiconductor pattern and the vertical conductive pattern, a gate pattern surrounding an upper surface, a lower surface, and the first side surfaces of the semiconductor pattern, and a data storage structure on a side surface of the first source/drain region of the source/drain regions.

According to some example embodiments of the present inventive concepts, a semiconductor device may include a substrate, a plurality of horizontal structures stacked and spaced apart from each other in a vertical direction perpendicular to an upper surface of the substrate, a plurality of interlayer insulating layers alternately stacked with the plurality of horizontal structures, and a plurality of vertical conductive patterns extending in the vertical direction based on penetrating through the plurality of horizontal structures and the plurality of interlayer insulating layers, and spaced apart from each other in a first horizontal direction that is parallel to the upper surface of the substrate. Each of the plurality of horizontal structures may include first structures spaced apart from each other in the first horizontal direction on a first side of the plurality of vertical conductive patterns, first conductive line patterns connecting the first structures to each other, second structures spaced apart from each other in the first horizontal direction on a second side of the plurality of vertical conductive patterns opposing the first side, and second conductive line patterns connecting the second structures to each other. Each of the first structures and the second structures may include a semiconductor pattern having first side surfaces opposing each other in the first horizontal direction and second side surfaces opposing each other in a second horizontal direction that is parallel to the upper surface of the substrate and perpendicular to the first horizontal direction, source/drain regions on the second side surfaces of the semiconductor pattern, a gate pattern surrounding an upper surface, a lower surface, and the first side surfaces of the semiconductor pattern, and a data storage structure extending in parallel to the semiconductor pattern in the second horizontal direction on one side of the source/drain regions.

### BRIEF DESCRIPTION OF THE DRAWINGS

The above and other aspects, features, and advantages of the present inventive concepts will be more clearly understood from the following detailed description, taken in combination with the accompanying drawings, in which:

FIG. 1A is a plan diagram illustrating a semiconductor device according to some example embodiments of the present inventive concepts;

FIG. 1B is a perspective diagram illustrating a semiconductor device according to some example embodiments of the present inventive concepts;

FIG. 2A is a plan diagram illustrating a semiconductor device according to some example embodiments of the present inventive concepts;

FIG. 2B is a cross-sectional diagram illustrating a semiconductor device according to some example embodiments of the present inventive concepts;

FIGS. 3, 4, 5, 6A, and 6B are plan diagrams illustrating a semiconductor device according to some example embodiments of the present inventive concepts;

FIGS. 7A and 7B are plan diagrams illustrating a semiconductor device according to some example embodiments of the present inventive concepts; and

FIGS. 8, 9A, 9B, 9C, 9D, 10A, 10B, 10C, 10D, 11A, 11B, 11C, 11D, 12A, 12B, 12C, 12D, 13, 14A, 14B, 14C, 14D, 15A, 15B, 15C, 15D, 16A, 16B, 16C, 16D, 17A, 17B, 17C, 17D, 18A, 18B, 18C, 18D, and 19 are perspective diagrams, plan diagrams, and cross-sectional diagrams illustrating a method of manufacturing a semiconductor device according to some example embodiments of the present inventive concepts.

### DETAILED DESCRIPTION

Hereinafter, some example embodiments of the present inventive concepts will be described as follows with reference to the accompanying drawings.

Hereinafter, the terms “above” or “on” may include not only those that are directly on in a contact manner, but also those that are above in a non-contact manner. The singular forms “a,” “an,” and “the” as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%)).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

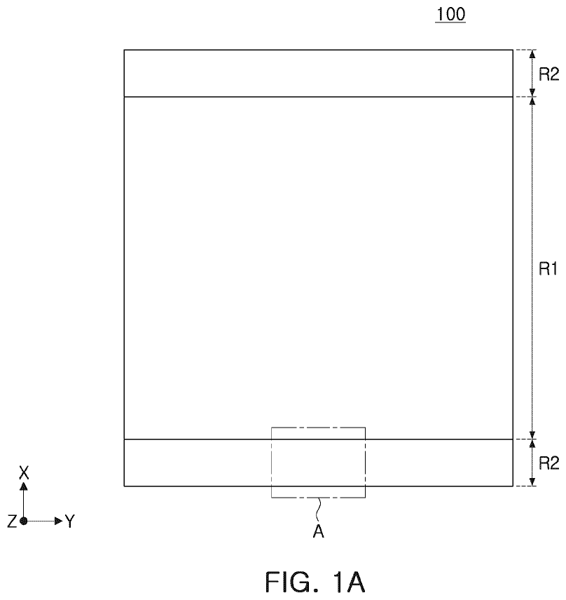

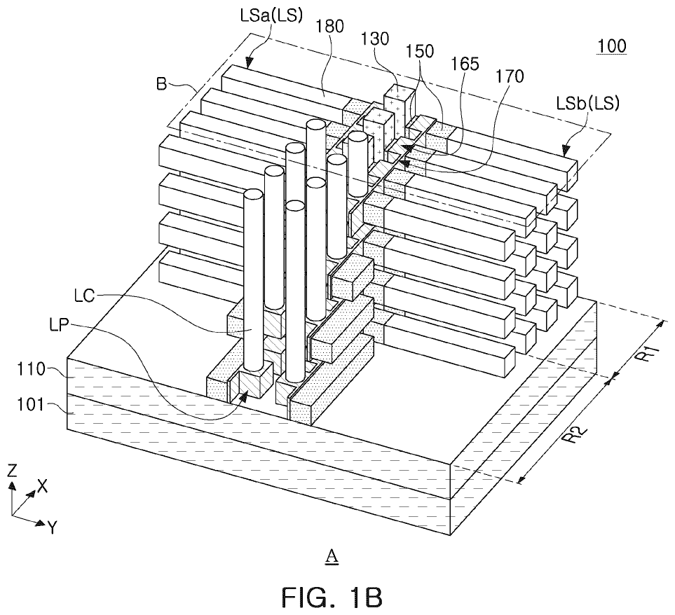

FIG. 1A is a plan diagram illustrating a semiconductor device according to some example embodiments.

FIG. 1B is a perspective diagram illustrating a semiconductor device according to some example embodiments, illustrating region “A” in FIG. 1A.

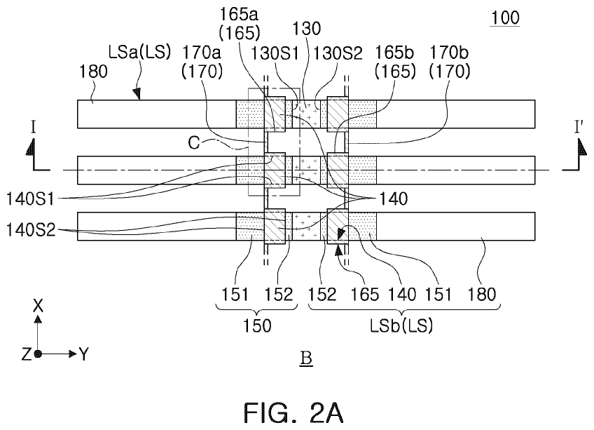

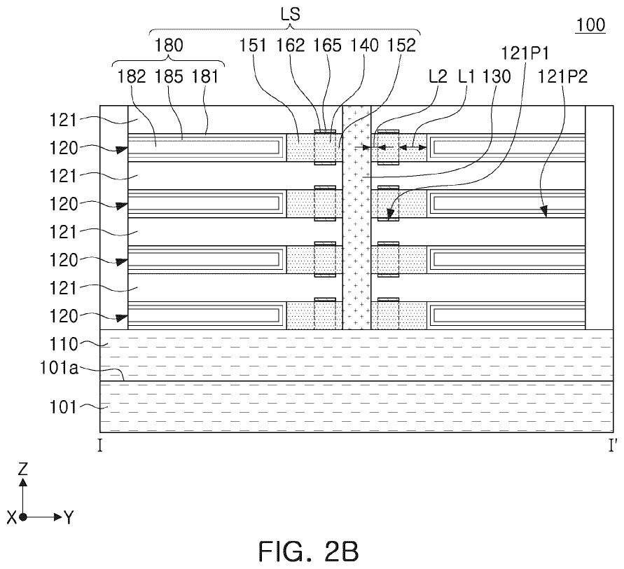

FIG. 2A is a plan diagram illustrating a semiconductor device according to some example embodiments, illustrating region “B” in FIG. 1B.

FIG. 2B is a cross-sectional diagram illustrating a semiconductor device according to some example embodiments, taken along line I-I′ in FIG. 2A.

Referring to FIGS. 1A to 2B, a semiconductor device 100 in some example embodiments may include a substrate 101, a plurality of horizontal structures 120 and a plurality of interlayer insulating layers 121 alternately stacked on the substrate 101, and a plurality of vertical conductive patterns 130 extending in the Z-direction by penetrating through the plurality of horizontal structures 120 and the plurality of interlayer insulating layers 121 on the substrate 101. The Z-direction may refer to a direction perpendicular to the upper surface 101a of the substrate 101. The plurality of horizontal structures 120 may include a plurality of structures LS each including a semiconductor pattern 140, source/drain regions 150, a gate pattern 165, and a data storage structure 180, and a plurality of conductive line patterns 170 connecting the plurality of structures LS to each other.

The semiconductor device 100 in some example embodiments may include a plurality of bit lines made up of (e.g., including) a plurality of vertical conductive patterns 130, a plurality of word lines made up of (e.g., including) a plurality of conductive line patterns 170, a memory cell transistor made up of (e.g., including) a plurality of structures LS, and a plurality of cell arrays having data storage elements. The cell array of the semiconductor device may correspond to a memory cell array of a dynamic random access memory (DRAM) device. In some example embodiments, the memory cell transistor may include a semiconductor pattern 140, source/drain regions 150 disposed on both sides (e.g., opposite sides) of the semiconductor pattern 140, and a gate pattern 165 surrounding at least a portion of the semiconductor pattern 140, and the data storage element may include a data storage structure 180. As will be described later, the data storage element may include a capacitor including a lower electrode, an upper electrode, and a dielectric layer, but some example embodiments thereof are not limited thereto.

Referring to FIGS. 1A and 1B, the substrate 101 may include a first region R1 and a second region R2. The first region R1 may be a cell region in which the memory cell transistor and the data storage elements are disposed, and the second region R2 may be for forming contacts for applying power to each of the plurality of word lines. The second region R2 may be disposed on at least one end of the first region R1. In some example embodiments, the second region R2 may be disposed on both ends of the first region R1 in the X-direction, but in some example embodiments, the second region R2 may be disposed on both ends (e.g., opposite ends) in the X-direction and on both ends (e.g., opposite ends) in the Y-direction, perpendicular to the X-direction so as to surround the entirety of surfaces of the first region R1. It will be understood that the X-direction, which may be referred to herein as a first horizontal direction, may extend parallel to the upper surface 101a of the substrate 101, and the Y-direction, which may be referred to herein as a second horizontal direction, may extend parallel to the upper surface 101a of the substrate 101 and perpendicular to the first horizontal direction (e.g., perpendicular to the X-direction).

The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be implemented as a silicon substrate, a silicon on insulator (SOI) substrate, a germanium substrate, a germanium on insulator (GOI) substrate, a silicon-germanium substrate, or a substrate including an epitaxial layer.

In some example embodiments, the semiconductor device 100 may further include a lower structure 110 disposed on the substrate 101. A plurality of horizontal structures 120 and a plurality of interlayer insulating layers 121 may be stacked (e.g., alternately stacked) on the lower structure 110. The lower structure 110 may include a device region on the substrate 101 and an insulating region covering the device region. The device region may include a conductive material such as a semiconductor material including impurities or a metal material. A plurality of vertical conductive patterns 130 may be in contact with the device region. The insulating region may include insulating layers including at least one of an insulating material, for example, silicon oxide, silicon nitride, silicon oxynitride, or silicon oxycarbide. However, in some example embodiments, the lower structure 110 may not be provided (e.g., may be absent).

The plurality of horizontal structures 120 and the plurality of interlayer insulating layers 121 may form a stack structure on the substrate 101. The plurality of horizontal structures 120 may be disposed between the plurality of interlayer insulating layers 121 and may be spaced apart from each other in the Z-direction by the plurality of interlayer insulating layers 121. The plurality of interlayer insulating layers 121 may include, for example, at least one of silicon oxide, silicon nitride, silicon oxynitride, or silicon oxycarbide.

Referring to FIGS. 2A and 2B, each of the plurality of interlayer insulating layers 121 may include a first portion 121P1, overlapping the gate pattern 165 of at least one structure of at least one horizontal structure in the Z-direction and a second portion 121P2 overlapping another portion of the at least one structure of at least one horizontal structure in the Z-direction. The thickness of the first portion 121P1 may be smaller than the thickness of the second portion 121P2. The difference between the thickness of the first portion 121P1 and the thickness of the second portion 121P2 may be due to the gate pattern 165.

Each of the plurality of horizontal structures 120 may include a plurality of structures LS spaced apart from each other, a plurality of conductive line patterns 170 connecting the plurality of structures LS to each other, and an insulating pattern (not illustrated) covering the side surfaces of the plurality of structures LS and the plurality of conductive line patterns 170.

The plurality of structures LS may include first structures LSa disposed spaced apart from each other in the X-direction on the first side 130S1 of the plurality of vertical conductive patterns 130, and second structures LSb spaced apart from each other in the X-direction on the second side 130S2 of the plurality of vertical conductive patterns 130. The second side 130S2 may be a surface opposite to the first side 130S1. The plurality of conductive line patterns 170 may include first conductive line patterns 170a connecting the first structures LSa and second conductive line patterns 170b connecting the second structures LSb.

Each of the first structures LSa and the second structures LSb may include a semiconductor pattern 140, source/drain regions 150, a gate pattern 165, and a data storage structure 180. Each of the first structures LSa and the second structures LSb may further include a dielectric pattern 162 between the gate pattern 165 and the semiconductor pattern 140. As shown in FIG. 2B, in some example embodiments, one or more of the interlayer insulating layers 121 may include a first portion 121P1 vertically overlapping (e.g., overlapping in the Z-direction) the gate pattern 165 of at least one structure LS of the first structure LSa or the second structure LSb of at least one horizontal structure 120 and a second portion 121P2 vertically overlapping the source/drain regions 150 and the data storage structure 180 of the at least one structure LS of the first structure LSa or the second structure LSb of the at least one horizontal structure 120.

The semiconductor pattern 140 may include a semiconductor material, for example, silicon, germanium, or silicon-germanium. The semiconductor pattern 140 may form a channel region of the memory cell transistor. The semiconductor pattern 140 may have first side surfaces 140S1 opposing each other in the X-direction and second side surfaces 140S2 opposing each other in the Y-direction.

The source/drain regions 150 may be disposed on the second side surfaces 140S2 of the semiconductor pattern 140. The source/drain regions 150 may include the same semiconductor material as the semiconductor pattern 140 and may have the same or substantially the same thickness and/or the same or substantially the same width as those of the semiconductor pattern 140. The source/drain regions 150 may be formed by doping the semiconductor material with impurities. The source/drain regions 150 may have n-type or p-type conductivity.

In some example embodiments, the source/drain regions 150 may include a first source/drain region 151 disposed on one side of the second side surfaces 140S2 of the semiconductor pattern 140 and a second source/drain region 152 disposed on an opposite side of the second side surfaces 140S2 of the semiconductor pattern 140 opposing the one side. One of the first source/drain region 151 or the second source/drain region 152 may correspond to the source region, and the other may correspond to the drain region.

The first source/drain region 151 may be disposed between the semiconductor pattern 140 and the data storage structure 180, and the second source/drain region 152 may be disposed between the semiconductor pattern 140 and the vertical conductive pattern 130. The first source/drain region 151 may connect the semiconductor pattern 140 to the data storage structure 180, and the second source/drain region 152 may connect the semiconductor pattern 140 to the vertical conductive pattern 130. In some example embodiments, the first source/drain region 151 may have a shape and/or a length different from those of the second source/drain region 152. For example, the first length L1 of the first source/drain region 151 in the Y-direction may be different from the second length L2 of the second source/drain region 152 in the Y-direction. This may be because the first length L1 of the first source/drain region 151 and the second length L2 of the second source/drain region 152 may be determined by additional processes. In some example embodiments, the first length L1 may be greater than the second length L2.

The gate pattern 165 may surround an upper surface, a lower surface, and the first side surfaces 140S1 of the semiconductor pattern 140 on the first region R1 of the substrate 101. That is, the gate pattern 165 may surround the semiconductor pattern 140 along a central axis of the semiconductor pattern 140 taken in the Y-direction. For example, in a semiconductor device 100 that includes a plurality of semiconductor patterns 140, the semiconductor device 100 may include a plurality of gate patterns 165 surrounding upper surfaces, lower surfaces, and the first side surfaces 140S1 of each of the plurality of semiconductor patterns 140, such that each separate gate pattern 165 surrounds an upper surface, a lower surface, and the first side surfaces of a separate semiconductor pattern 140 of the plurality of semiconductor patterns 140.

A semiconductor device 100 having improved electrical properties may be provided by the structure of the gate pattern 165 surrounding the four surfaces (upper surface, lower surface, and first side surfaces 140S1) of the semiconductor pattern 140. A semiconductor device 100 having improved electrical properties and integration density may be provided based on the semiconductor device 100 including a plurality of semiconductor patterns 140 spaced apart from each other horizontally (e.g., in the X-direction) and vertically (e.g., in the Z-direction) and gate patterns 165 surrounding each of the four surfaces of each of the plurality of semiconductor patterns 140. A semiconductor device 100 having improved electrical properties and integration density may be provided based on the semiconductor device 100 including at least one conductive line pattern 170 horizontally connecting at least some of the gate patterns 165 to each other (e.g., electrically connecting gate patterns 165 that overlap each other in the X-direction) a where the gate patterns 165 at a given position in the Z-direction are electrically connected horizontally (e.g., in the X-direction by other). A semiconductor device 100 having improved electrical properties and integration density may be provided based on the semiconductor device 100 including a plurality of structures LS that each include the semiconductor patterns 140, the first and second source/drain regions 151 and 152, the gate patterns 165, and the data storage structure 180, where the plurality of structures LS are spaced apart from each other (e.g., in the X-direction and the Z-direction). A semiconductor device 100 having improved electrical properties and integration density may be provided based on the semiconductor device 100 including horizontal structures 120, spaced apart in the Z-direction by one or more interlayer insulating layers 121, which include first and second structures LSa and LSb spaced apart from each other and on opposite sides of a vertical conductive pattern 130, where each of the first and second structures LSa and LSb includes a semiconductor pattern 140, the first and second source/drain regions 151 and 152, a gate pattern 165 surrounding an upper surface, a lower surface, and the first side surfaces 140S1 of the semiconductor pattern 140, and a data storage structure 180 on a side surface of the first source/drain region 151. Improved integration density of a semiconductor device 100 may result in improved compactness, miniaturization, etc. of the semiconductor device 100. Additionally, by including such a semiconductor device 100 having improved electrical properties and integration density in a manufactured electronic device, an electronic device having improved electrical properties and integration density may be provided. In some example embodiments, the gate pattern 165 may have a uniform or substantially uniform thickness and may surround the semiconductor pattern 140.

The gate pattern 165 may include a conductive material, and the conductive material may include at least one of a doped semiconductor material (e.g., doped silicon or doped germanium), a conductive metal nitride (e.g., titanium nitride, tantalum nitride, or tungsten nitride), metals (e.g., tungsten, titanium, tantalum, cobalt, aluminum, or ruthenium), or a metal-semiconductor compound (e.g., tungsten silicide, cobalt silicide, or titanium silicide).

The dielectric pattern 162 may be disposed to have a conformal thickness between the gate pattern 165 and the semiconductor pattern 140. Gate dielectric layer 142 may include silicon oxide, silicon nitride, or a high-x material. The high-x material may refer to a dielectric material having a higher dielectric constant than that of silicon oxide (SiO₂). The high-x material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃), where 0≤x≤7 and 0≤y≤7.

The data storage structure 180 may be disposed to extend in parallel to the semiconductor pattern 140 in the Y-direction on the side surface of the first source/drain region 151. The data storage structure 180 may be electrically connected to the semiconductor pattern 140 and the first source/drain region 151. In some example embodiments, the data storage structure 180 may include a first electrode 181, a dielectric layer 185 on the first electrode 181, and a second electrode 182 on the dielectric layer 185. The data storage structure may have a cylinder shape as illustrated in FIG. 2B, but some example embodiments thereof are not limited thereto and the data storage structure may have a pillar shape in some example embodiments. The first and second electrodes 181 and 182 may include at least one of a doped semiconductor material, a conductive metal nitride, a metal, or a metal-semiconductor compound, and the dielectric layer 185 may include, for example, at least one of a high-K material, such as zirconium oxide (ZrO₂), aluminum oxide (Al₂O₃), or hafnium oxide (Hf₂O₃).

As the first structures LSa are spaced apart from each other in the X-direction in one horizontal structure 120, the plurality of semiconductor patterns 140 in the first structures LSa may be spaced apart from each other in the X-direction, and the plurality of gate patterns 165 in the first structures LSa may surround the plurality of semiconductor patterns 140, respectively (e.g., each of the gate patterns 165 may surround a separate semiconductor pattern 140). The second structures LSb may be described the same or similarly to the above example.

The plurality of conductive line patterns 170 may connect the gate patterns 165 of the plurality of structures LS to each other. The plurality of conductive line patterns 170 may electrically connect the gate patterns 165 of the plurality of structures LS spaced apart from each other in the X-direction within one horizontal structure 120 to each other.

Each of the plurality of conductive line patterns 170 may extend in the X-direction between a plurality of adjacent gate patterns 165 (e.g., between adjacent gate patterns 165 of the plurality of gate patterns 165), including adjacent gate patterns 165 that are at a same level in the Z-direction and thus at least partially overlap each other in the X-direction, such that each conductive line pattern 170 may connect at least adjacent gate patterns 165, in the X-direction, of a plurality of gate patterns 165 that are at a same level in the Z-direction and thus at least partially overlap each other in the X-direction. An upper surface of each of the plurality of conductive line patterns 170 may be coplanar with an upper surface of each of the plurality of adjacent gate patterns 165 that are connected by the conductive line pattern 170. A lower surface of each of the plurality of conductive line patterns 170 may be coplanar with a lower surface of each of the plurality of adjacent gate patterns 165, including the adjacent gate patterns 165 in the X-direction that are connected with a conductive line pattern 170 that is therebetween in the X-direction. A length of each of the plurality of conductive line patterns 170 in the Z-direction may be the same or substantially the same (e.g., may be a substantially same length) as a length of each of the plurality of gate patterns 165 in the Z-direction. A thickness of each of the plurality of conductive line patterns 170 may be the same or substantially the same (e.g., may be a substantially same thickness) as that of each of the plurality of gate patterns 165. A thickness of the plurality of conductive line patterns 170 may be defined in the Y-direction.

As shown, each of the first conductive line patterns 170a may extend between adjacent first gate patterns 165a in the X-direction, each of the second conductive line patterns 170b may extend between adjacent second gate patterns 165b in the X-direction, and the first conductive line patterns 170a may be spaced apart from the second conductive line patterns 170b in the Y-direction. On a plane (e.g., a first plane in the X and Z-directions), one side surface of each of the first conductive line patterns 170a may be coplanar with one side surface of adjacent first gate patterns 165a that the first conductive line pattern 170a is between in the X-direction and/or may be coplanar with one side surface of each of the first gate patterns 165a. In another plane (e.g., a second plane in the X and Z-directions) one side surface of each of the second conductive line patterns 170b may be coplanar with one side surface of adjacent second gate patterns 165b that the second conductive line pattern 170b is between in the X-direction and/or may be coplanar with one side surface of each of the second gate patterns 165b.

Each of the plurality of conductive line patterns 170 may be integrally connected to each of the plurality of gate patterns 165 to which the conductive line pattern 170 is connected. For example, each conductive line pattern 170 that connects adjacent gate patterns 165 in the X-direction may be integrally connected to each of said adjacent gate patterns 165, such that the conductive line pattern 170 and the plurality of gate patterns 165 connected thereto are separate portions of a single, unitary piece of material. For example, each of the plurality of conductive line patterns 170 may be integrally connected to adjacent (e.g., adjacent in the X-direction) gate patterns 165 of the plurality of gate patterns 165, such as in example embodiments where each of the plurality of conductive line patterns 170 extends in the X-direction between the adjacent gate patterns 165. In example embodiments where a plurality of conductive line patterns 170 connect, and are integrally connected to, separate sets of adjacent gate patterns 165 of a plurality of gate patterns 165 in the X-direction, where the plurality of gate patterns 165 are at least partially overlapped with each other in the X-direction, such that the conductive line patterns 170 and the gate patterns 165 alternate in the X-direction, the entire plurality of conductive line patterns 170 and the plurality of gate patterns 165 may be separate portions of a single, unitary piece of material extending in the X-direction. This may be because the plurality of conductive line patterns 170 and the plurality of gate patterns 165 may be formed through the same deposition process.

The plurality of conductive line patterns 170 may include a conductive material, and the conductive material may include at least one of a doped semiconductor material (e.g., doped silicon or doped germanium), a conductive metal nitride (e.g., titanium nitride, tantalum nitride, or tungsten nitride), a metal (e.g. tungsten, titanium, tantalum, cobalt, aluminum, or ruthenium), or a metal-semiconductor compound (e.g., tungsten silicide, cobalt silicide, or titanium silicide). The plurality of conductive line patterns 170 may include the same material (e.g., may include a material that is a same material) as a material of the plurality of gate patterns 165.

A plurality of semiconductor patterns 140 spaced apart from each other in the X-direction within one horizontal structure 120 may be electrically connected by a plurality of conductive line patterns 170. Accordingly, the plurality of semiconductor patterns 140 may have a horizontal word line (lateral WL) structure. In this case, the semiconductor patterns 140 disposed in different horizontal structures 120 may be spaced apart from each other in the Z-direction by interlayer insulating layers 121.

The plurality of vertical conductive patterns 130 may vertically extend in the Z-direction on the substrate 101. Each of the plurality of vertical conductive patterns 130 may have a line shape, a bar shape, or a column shape. For example, the plurality of vertical conductive patterns 130 may have a square pillar shape, but some example embodiments thereof are not limited thereto. Although not illustrated, the semiconductor device 100 may further include an upper wiring disposed on the plurality of vertical conductive patterns 130 and connected to the plurality of vertical conductive patterns 130. The plurality of vertical conductive patterns 130 may include at least one of a doped semiconductor material, a conductive metal nitride, a metal, or a metal-semiconductor compound.

The semiconductor device 100 according to some example embodiments may further include landing patterns LP and landing contacts LC disposed on the second region R2 of the substrate 101.

The landing patterns LP may be disposed in parallel to the semiconductor patterns 140 and spaced apart from each other in the X-direction within the horizontal structures 120. Each of the landing patterns LP may be connected to the gate patterns 165 by conductive line patterns 170.

Each of the landing contacts LC may be in contact with the landing patterns LP of the horizontal structures 120, respective. The gate patterns 165 spaced apart from each other in the X-direction within one horizontal structure 120 may be electrically connected through the landing pattern LP and the conductive line patterns 170 by power applied to the landing contact LC. Accordingly, the horizontal word line structure may be formed.

Referring to FIGS. 2A and 2B, with respect to the central axis of the plurality of vertical conductive patterns 130 in the X-direction, the first structures LSa and the first conductive line patterns 170a may be symmetrical to the second structures LSb and the second conductive line patterns 170b. In this case, each of the plurality of vertical conductive patterns 130 may simultaneously apply power to the first and second structures LSa and LSb on the first and second sides 130S1 and 130S2, and each of the vertical conductive patterns 130 may simultaneously apply power to the plurality of structures LS disposed on the plurality of horizontal structures 120.

However, in some example embodiments, the symmetrical shape may be varied depending on process conditions of a patterning process for forming the semiconductor pattern 140.

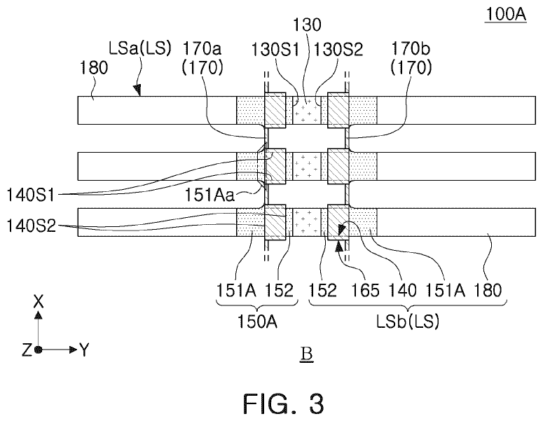

In the description below, various modifications of a semiconductor device according to example embodiments will be described with reference to FIGS. 3 to 7B.

FIG. 3 is a plan diagram illustrating a semiconductor device according to some example embodiments, illustrating a region corresponding to FIG. 2A.

Referring to FIG. 3, in the semiconductor device 100A, a source/drain region 150A may have a structure different from some example embodiments, including the example embodiments shown in FIG. 2A. For example, the source/drain regions 150A may each include a first source/drain region 151A and a second source/drain region 152, where the width of the first source/drain region 151A in the X-direction may include a portion increasing in the direction from the data storage structure 180 toward the semiconductor pattern 140. The portion may be disposed in a portion 151Aa of the first source/drain region 151A that is adjacent to the semiconductor pattern 140, such that, in the portion 151Aa, the width of a cross-section of the first source/drain region 151A in the X-direction increases with increased proximity of the cross-section to the semiconductor pattern 140 in the Y-direction. This may be formed by partially remaining the preliminary first source/drain region in an etching process of patterning the preliminary first source/drain region extending in the X-direction. The portion of the first source/drain region 151A may have an inwardly curved surface, but the shape of the portion may be varied.

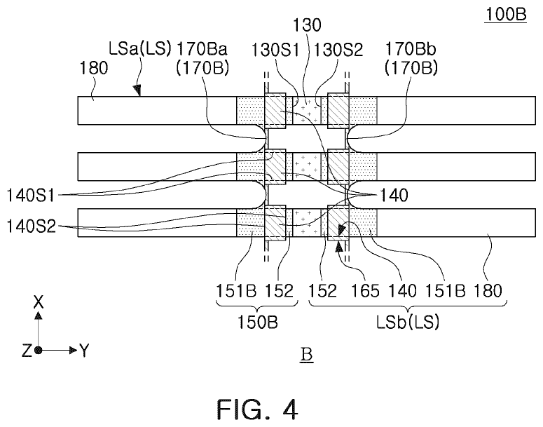

FIG. 4 is a plan diagram illustrating a semiconductor device according to some example embodiments, illustrating a region corresponding to FIG. 2A.

Referring to FIG. 4, in the semiconductor device 100B, a source/drain region 150B may have a structure different from some example embodiments, including the example embodiments shown in FIG. 2A, for example the source/drain regions 150B may each include a first source/drain region 151B and a second source/drain region 152. Still referring to FIG. 4, in the semiconductor device 100B, the plurality of conductive line patterns 170B may not have a uniform or substantially uniform thickness. For example, on a plane, the plurality of conductive line patterns 170B, which may include first conductive line patterns 170Ba connecting the first structures LSa and second conductive line patterns 170Bb connecting the second structures LSb, may have a portion coplanar with the first source/drain region 151B. This may be because a portion of the plurality of conductive line patterns 170B may also be removed during the etching process of forming the first source/drain region 151B. The curvature of the first source/drain region 151B and the curvature of the plurality of conductive line patterns 170B are illustrated as the same, but in some example embodiments, the shape of the coplanar surface may be varied such that the curvature of the first source/drain region 151B may be different from the curvature of the plurality of conductive line patterns 170B portion. This may be because the etching rates of the plurality of conductive line patterns 170B and the first source/drain region 151B may be different.

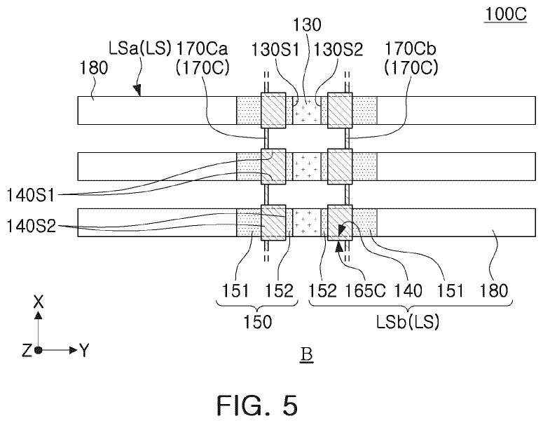

FIG. 5 is a plan diagram illustrating a semiconductor device according to some example embodiments, illustrating a region corresponding to FIG. 2A.

Referring to FIG. 5, in the semiconductor device 100C, the plurality of conductive line patterns 170C, which may include first conductive line patterns 170Ca connecting the first structures LSa and second conductive line patterns 170Cb connecting the second structures LSb may not be aligned with the gate patterns 165C in the X-direction. That is, on a plane, the side surfaces of the plurality of conductive line patterns 170C in the X-direction may not overlap the side surfaces of the gate patterns 165C taken in the X-direction in the X-direction.

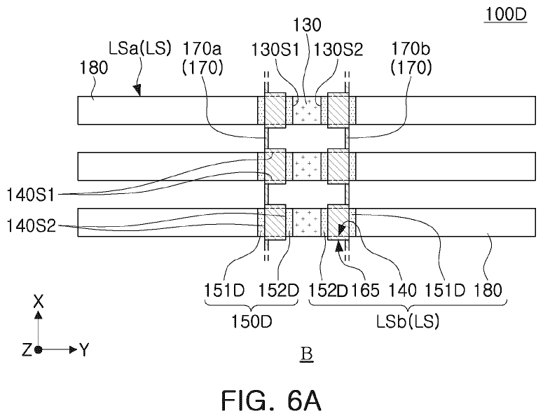

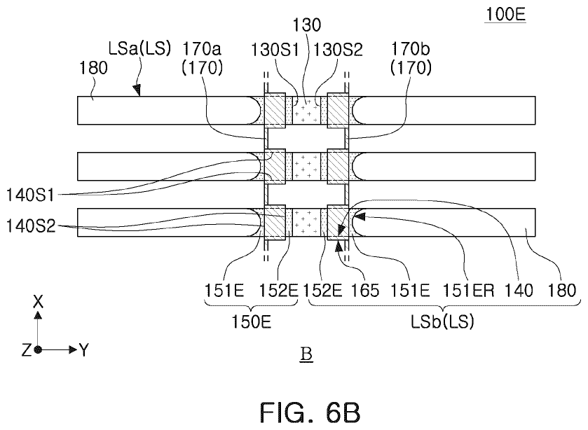

FIG. 6A is a plan diagram illustrating a semiconductor device according to some example embodiments, illustrating a region corresponding to FIG. 2A.

Referring to FIG. 6A, in the semiconductor device 100D, a source/drain region 150D may have a structure different from some example embodiments, including the example embodiments shown in FIG. 2A. For example, the source/drain regions 150D may each include a first source/drain region 151D and a second source/drain region 152D. The first length L1′ of the first source/drain region 151D of the source/drain region 150D in the Y-direction may be the same or substantially the same as the second length L2′ of the second source/drain region 152D in the Y-direction. This may be formed by adjusting process conditions for determining the lengths of the first source/drain region 151D and the second source/drain region 152D. For example, the length of the first source/drain region 151D may be relatively reduced by adjusting the etching degree of the sacrificial layers 118 with respect to the interlayer insulating layers 121, or the length of the second source/drain region 152D may be relatively increased by adjusting the etching degree of the metal material layer surrounding the semiconductor material layer in the etching process, thereby providing the semiconductor device 100D in some example embodiments, including the example embodiments shown in FIG. 6A.

FIG. 6B is a plan diagram illustrating a semiconductor device according to some example embodiments, illustrating a region corresponding to FIG. 2A.

Referring to FIG. 6B, in the semiconductor device 100E, a source/drain region 150E may have a structure different from some example embodiments, including the example embodiments shown in FIG. 2A. For example, the source/drain regions 150E may each include a first source/drain region 151E and a second source/drain region 152E. The first source/drain region 151E of the source/drain region 150E may have a recess portion 151ER in contact with the data storage structure 180 and recessed by the data storage structure 180. The recess portion 151ER may be filled with the data storage structure 180. This may be formed by partially removing the first source/drain region 151E by the process of etching the sacrificial layer for forming the data storage structure 180.

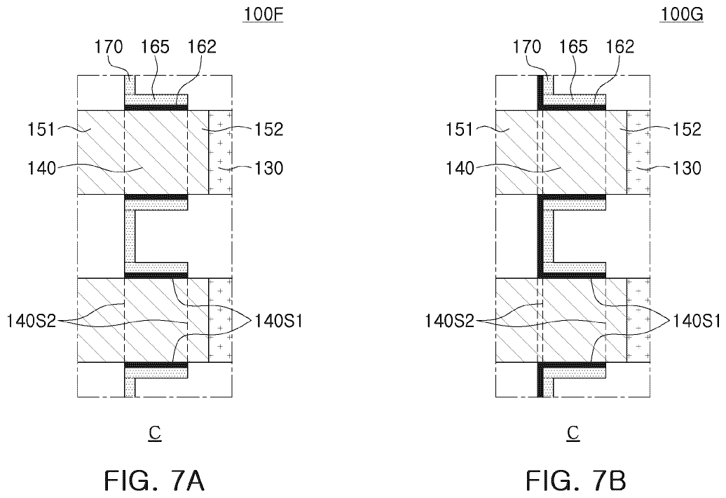

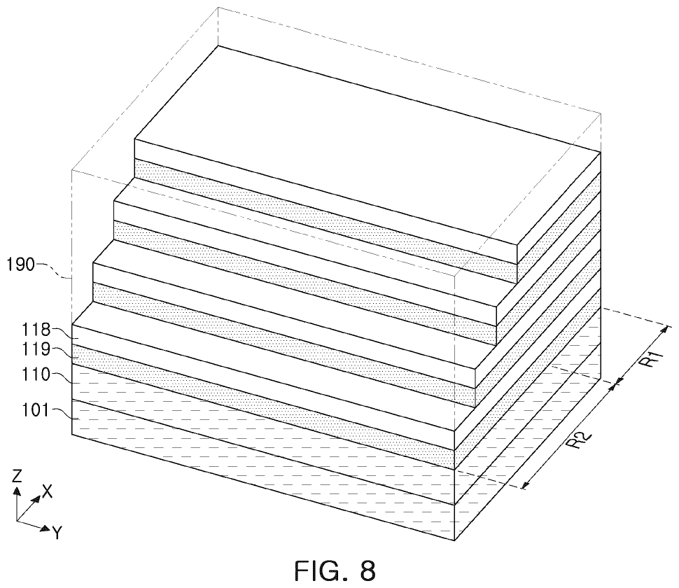

FIGS. 7A and 7B are plan diagrams illustrating a semiconductor device according to some example embodiments, illustrating a region corresponding to region “C” in FIG. 2A.

Referring to FIG. 7A, in the semiconductor device 100F, the dielectric pattern 162 may surround upper surfaces, lower surfaces and the first side surfaces 140S1 of the semiconductor pattern 140 between the gate pattern 165 and the semiconductor pattern 140. The length of the dielectric pattern 162 in the X-direction may be the same or substantially the same as the length of the gate pattern 165 in the X-direction, but some example embodiments thereof are not limited thereto, and the length of the dielectric pattern 162 may be longer.

Referring to FIG. 7B, in the semiconductor device 100G, the dielectric pattern 162 may include a portion disposed between the gate pattern 165 and the semiconductor pattern 140 and may further include a portion extending therefrom and extending to the side surface of the plurality of conductive line patterns 170.

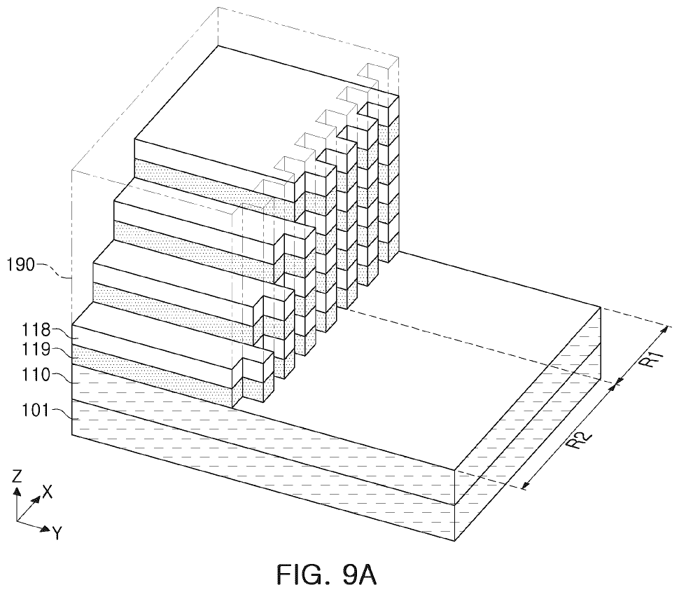

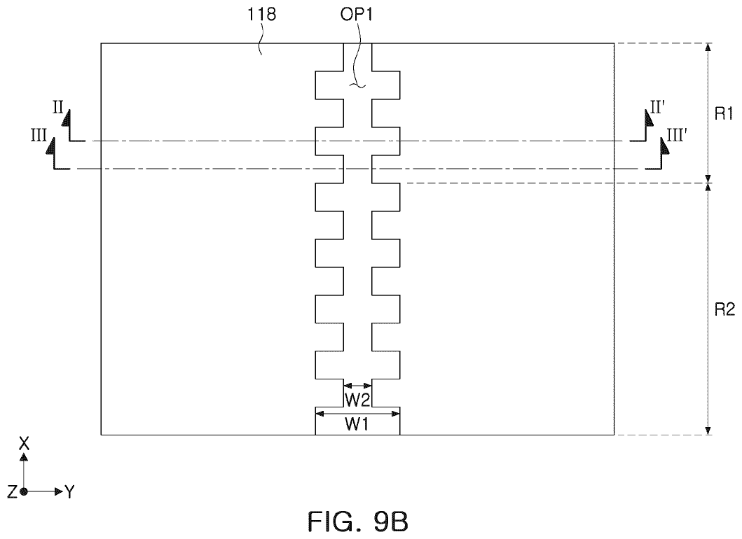

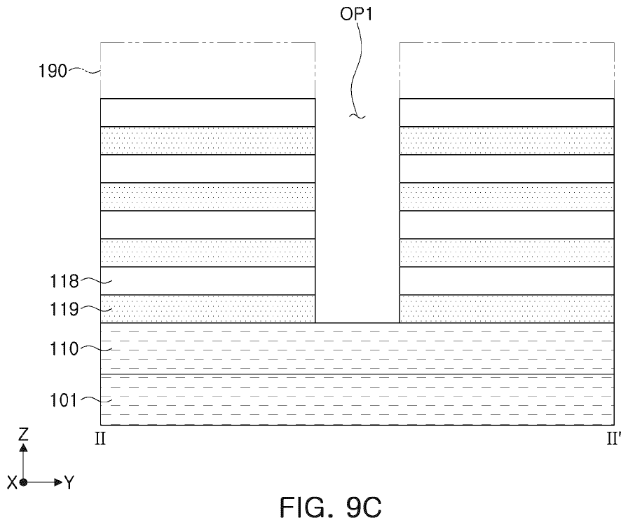

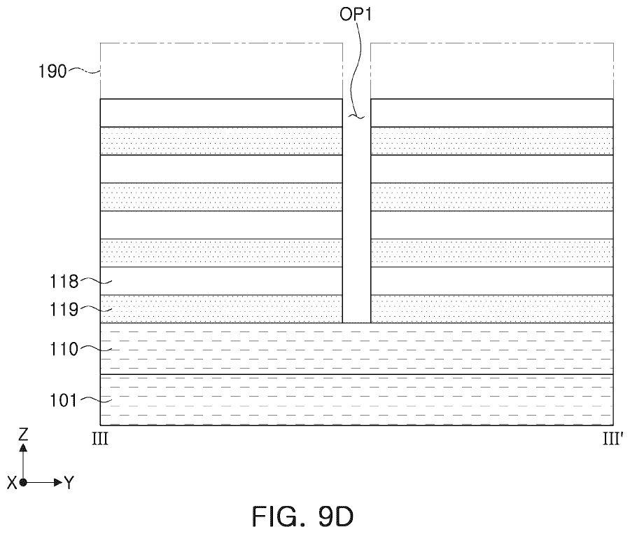

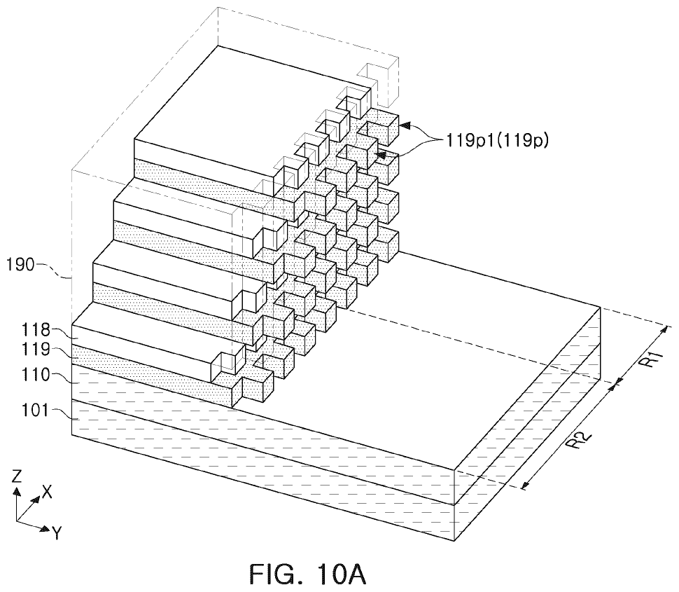

FIGS. 8, 9A, 9B, 9C, 9D, 10A, 10B, 10C, 10D, 11A, 11B, 11C, 11D, 12A, 12B, 12C, 12D, 13, 14A, 14B, 14C, 14D, 15A, 15B, 15C, 15D, 16A, 16B, 16C, 16D, 17A, 17B, 17C, 17D, 18A, 18B, 18C, 18D, and 19 are perspective diagrams, plan diagrams, and cross-sectional diagrams illustrating a method of manufacturing a semiconductor device according to some example embodiments. FIGS. 8, 9A, 10A, 11A, 12A, 13, 14A, 15A, 16A, 17A, 18A, and 19 are perspective diagrams illustrating a method of manufacturing a semiconductor device according to example embodiments. FIGS. 9B, 10B, 11B, 12B, 14B, 15B, 16B, 17B, and 18B are plan diagrams corresponding to FIGS. 9A, 10A, 11A, 12A, 14A, 15A, 16A, 17A, and 18A, respectively. FIGS. 9C, 10C, 11C, 12C, 14C, 15C, 16C, 17C, and 18C are cross-sectional diagrams taken along line II-II′ in FIGS. 9B, 10B, 11B, 12B, 14B, 15B, 16B, 17B, and 18B, respectively. FIGS. 9D, 10D, 11D, 12D, 14D, 15D, 16D, 17D, and 18D are cross-sectional diagrams taken along line III-III′ in FIGS. 9B, 10B, 11B, 12B, 14B, 15B, 16B, 17B, and 18B, respectively.

Referring to FIG. 8, a lower structure 110 may be formed on a substrate 101, sacrificial layers 118 and semiconductor layers 119 may be alternately layered in the Z-direction, and a trimming process may be performed, thereby forming a stack structure.

The sacrificial layers 118 may be formed of a material different from that of the semiconductor layers 119. For example, the semiconductor layers 119 may be formed of silicon, and the sacrificial layers 118 may be formed of silicon-germanium, silicon oxide, silicon nitride, silicon carbide, or silicon oxynitride. The sacrificial layers 118 may be formed to have a thickness greater than that of the semiconductor layers 119 in the Z-direction, but some example embodiments thereof are not limited thereto. The sacrificial layers 118 may be replaced with interlayer insulating layers 121 (see FIG. 2B) through a subsequent process. A portion of the semiconductor layers 119 may remain as a source/drain region 150 (see FIG. 2B) and a semiconductor pattern 140 (see FIG. 2B) through a subsequent process, and the other portion may be a plurality of horizontal structures 120 (see FIG. 2B) filled with data storage structures 180.

The trimming process may include removing portions of the sacrificial layers 118 and semiconductor layers 119 such that a portion of the upper surfaces of each of the sacrificial layers 118 are exposed by repeatedly performing exposure and etching processes using a mask pattern. Accordingly, the stack structure having a staircase structure may be formed. In the stack structure, sacrificial layers 118 and semiconductor layers 119 may be alternately stacked on the first region R1 of the substrate 101 without being removed, and a portion of the sacrificial layers 118 and the semiconductor layers 119 may be removed from the second region R2 of the substrate 101 to have a stepped structure.

The stack structure may include four sacrificial layers 118 and four semiconductor layers 119 alternately stacked, but the number of the sacrificial layers 118 and the semiconductor layers 119 is not limited thereto and may be varied.

A gap-fill insulating layer 190 covering the stack structure may be formed on the substrate 101 and a planarization process may be performed.

Referring to FIGS. 9A, 9B, 9C, and 9D, the first opening OP1 may be formed using a mask pattern.

Through an exposure and etching process using a mask pattern, a first opening OP1 penetrating the stack structure and exposing the lower structure 110 may be formed. The first opening OP1 may have a trench shape extending in one direction (e.g., X-direction) to alternately have a portion having a first width W1 and a portion having a second width W2 different from the first width W1 on the first and second regions R1 and R2. The first width W1 may be greater than the second width W2.

The lengths of the semiconductor pattern 140 (see FIG. 2A) and the second source/drain region 152 (see FIG. 2A) in the Y-direction formed through a subsequent process may be determined by the difference between the first width W1 and the second width W2.

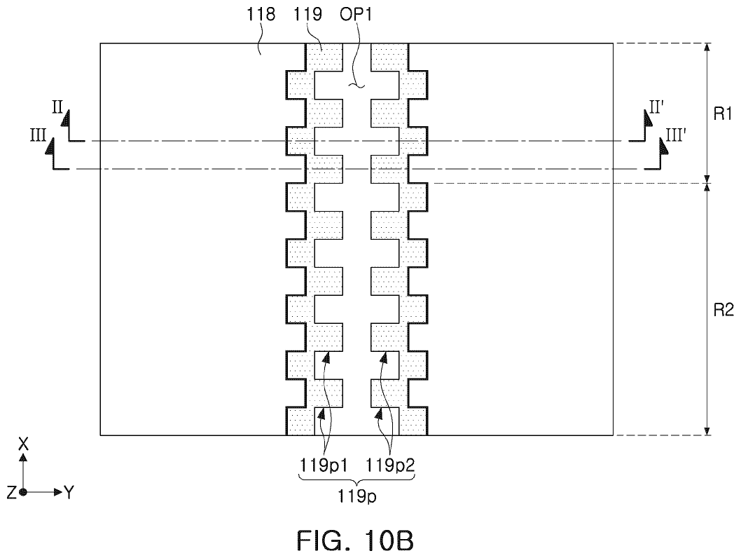

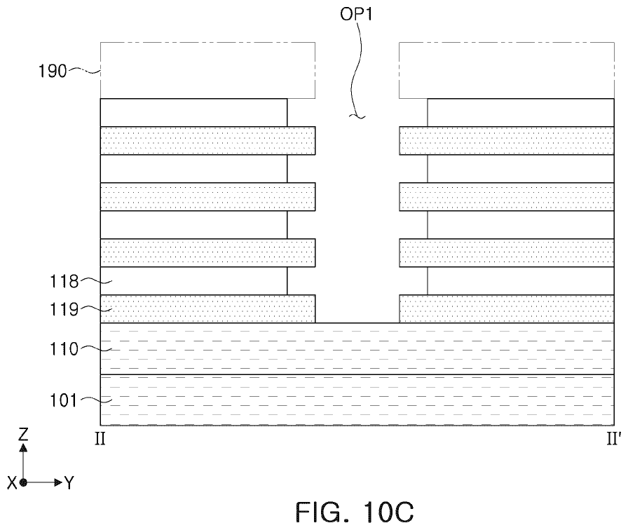

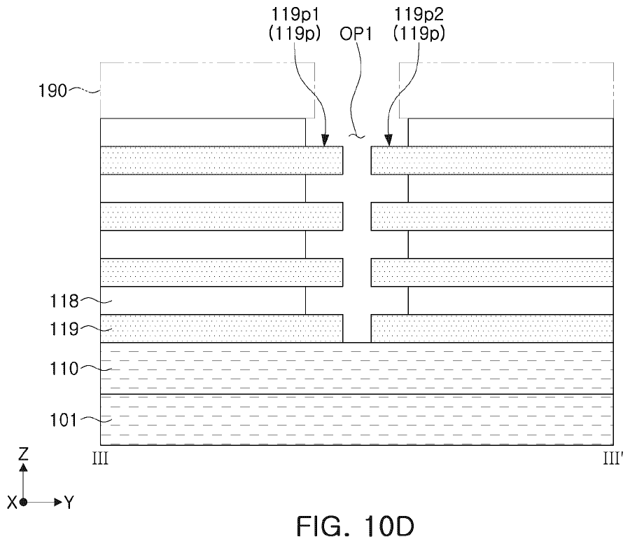

Referring to FIGS. 10A, 10B, 10C, and 10D, protrusions 119p of each of the semiconductor layers 119 may be formed by an etching process for selectively removing the sacrificial layers 118.

Protrusions 119p having at least four surfaces exposed may be formed by selectively removing the sacrificial layers 118 exposed through the first opening OP1 with respect to the semiconductor layers 119. In each of the semiconductor layers 119, the protrusions 119p may include first protrusions 119p1 spaced apart from each other in the X-direction and second protrusions 119p2 spaced apart from the first protrusions 119p1 and spaced apart from each other in the X-direction.

The etching process may be, for example, a wet etching process for removing only silicon-germanium from silicon. Through the etching process, portions of the upper surfaces of the semiconductor layers 119 may be exposed together with the protrusions 119p. The length of the first source/drain region 151 (see FIG. 2A) in the Y-direction, formed through a subsequent process, may be determined by the depth of the sacrificial layers 118 removed in the etching process.

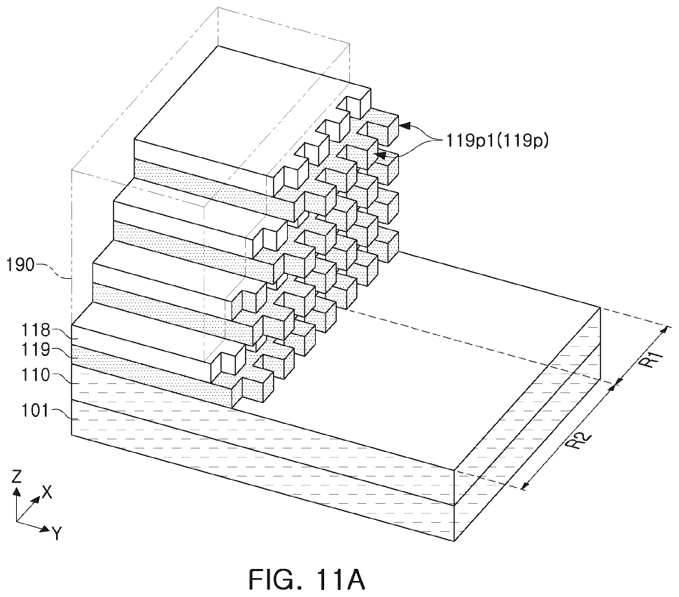

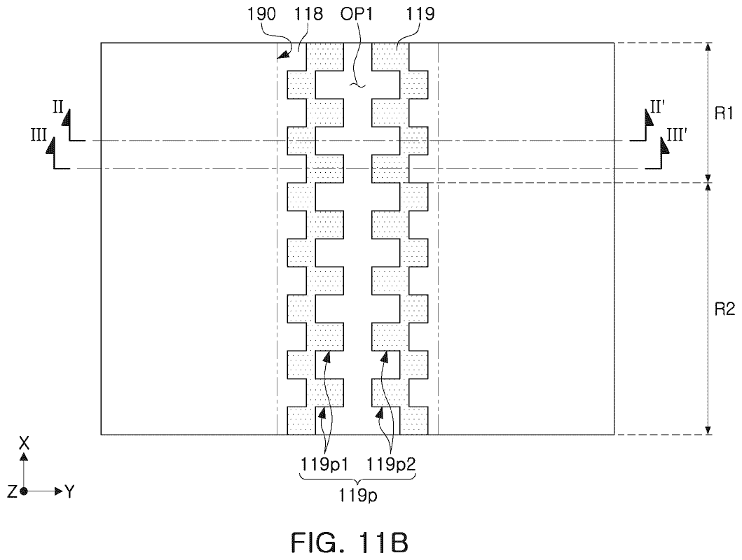

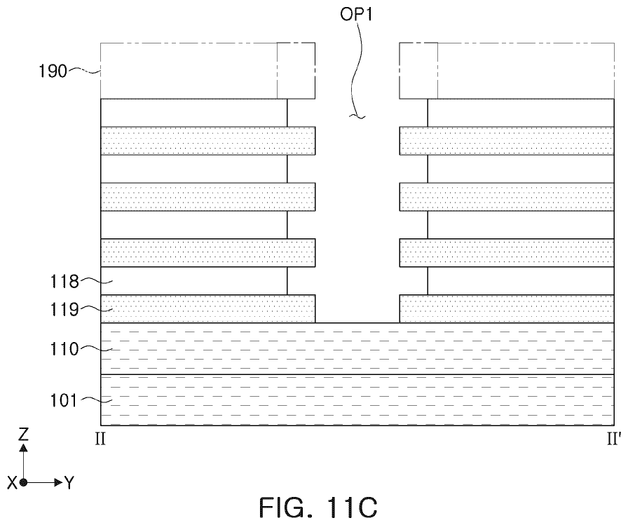

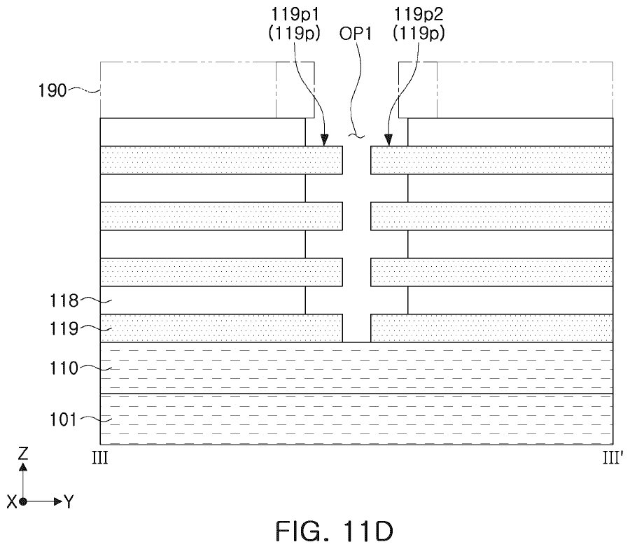

Referring to FIGS. 11A, 111B, 11C, and 11D, a portion of the gap-fill insulating layer 190 may be removed.

A portion of the gap-fill insulating layer 190 may be removed using a mask pattern having a shape the same as or similar to that of the first opening OP1. Accordingly, portions of the protrusions 119p and/or the uppermost sacrificial layer 118 may be exposed. In this process, as a portion of the gap-fill insulating layer 190 is removed, it may be easier to form and remove a metal material layer formed through a subsequent process. However, in some example embodiments, this process may not be performed.

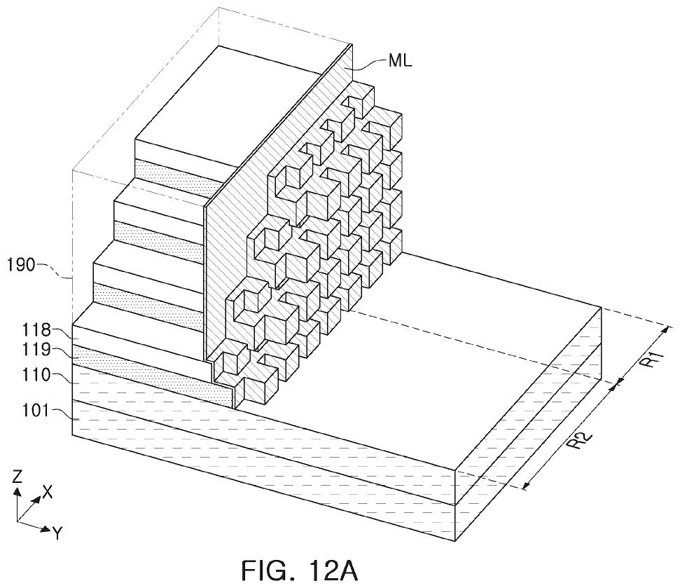

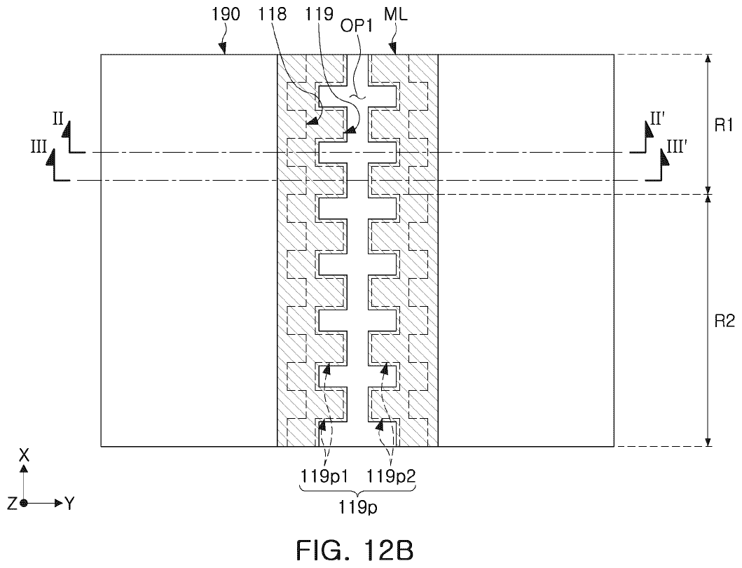

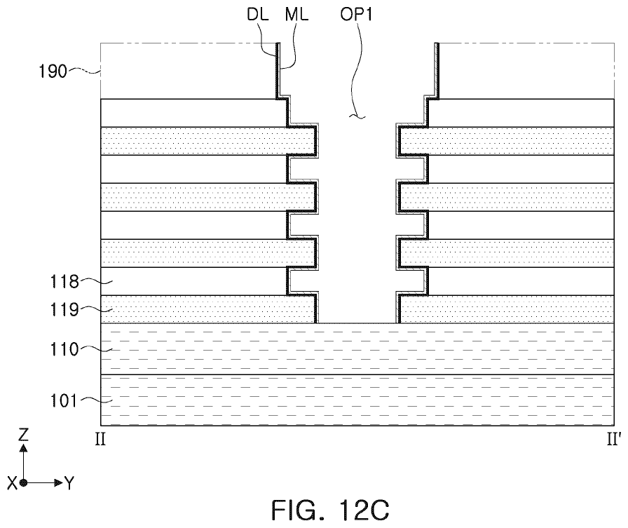

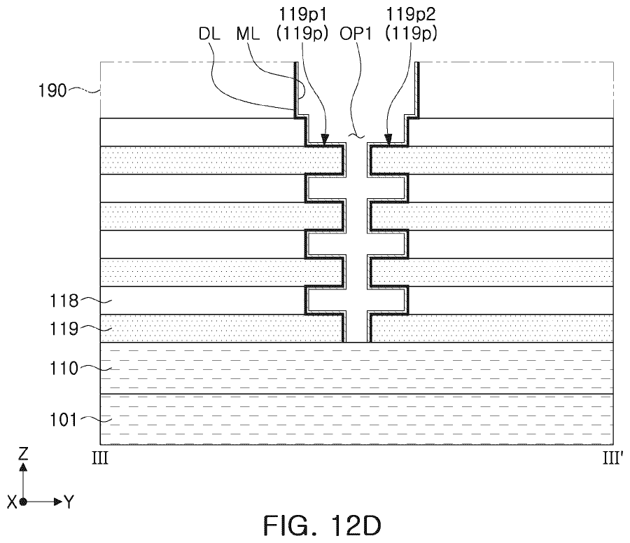

Referring to FIGS. 12A, 12B, 12C, and 12D, a dielectric material layer DL and a metal material layer ML may be formed.

A dielectric material layer DL and a metal material layer ML conformally covering the sacrificial layers 118 and the semiconductor layers 119 exposed through the first opening OP1 may be formed by performing a deposition process and an etching process. Through the deposition process, the dielectric material layer DL and the metal material layer ML may be formed to have uniform or substantially uniform thicknesses. The dielectric material layer DL and the metal material layer ML may cover exposed surfaces of the protrusions 119p. In some example embodiments, the dielectric material layer DL may be formed to have a thickness smaller than that of the metal material layer ML, but some example embodiments thereof are not limited thereto. The etching process may be of removing portions of the dielectric material layer DL and the metal material layer ML disposed on the gap-fill insulating layer 190 and the lower structure 110. The dielectric material layer DL may include silicon oxide, silicon nitride, or a high-x material. The high-x material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃), where 0≤x≤7 and 0≤y≤7. The metal material layer ML may include a conductive material, and the conductive material may include at least one of a doped semiconductor material (e.g., doped silicon or doped germanium), a conductive metal nitride (e.g., titanium nitride, tantalum nitride, or tungsten nitride), a metal (e.g., tungsten, titanium, tantalum, cobalt, aluminum, or ruthenium), or a metal-semiconductor compound (e.g., tungsten silicide, cobalt silicide, or titanium silicide).

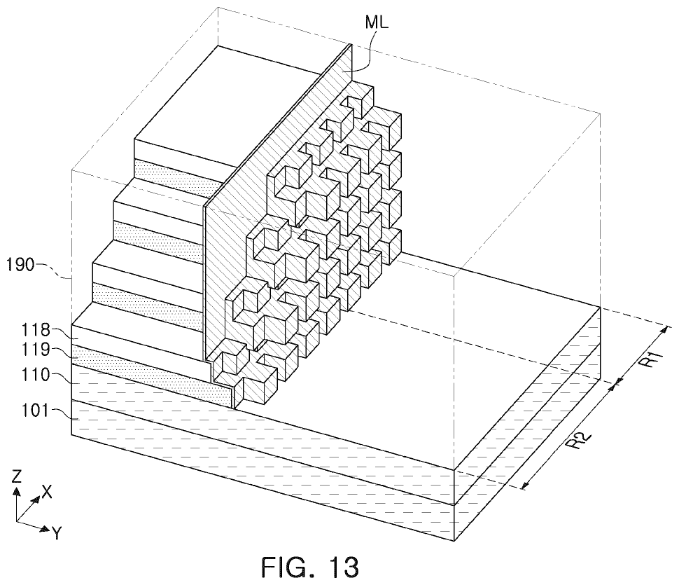

Referring to FIG. 13, a gap-fill insulating layer 190 may be additionally formed.

A gap-fill insulating layer 190 may be additionally formed to cover the first opening OP1 by depositing an insulating material and performing a planarization process. However, in some example embodiments, the existing gap-fill insulating layer 190 and the gap-fill insulating layer 190 filling the first opening OP1 in this process may include different insulating materials.

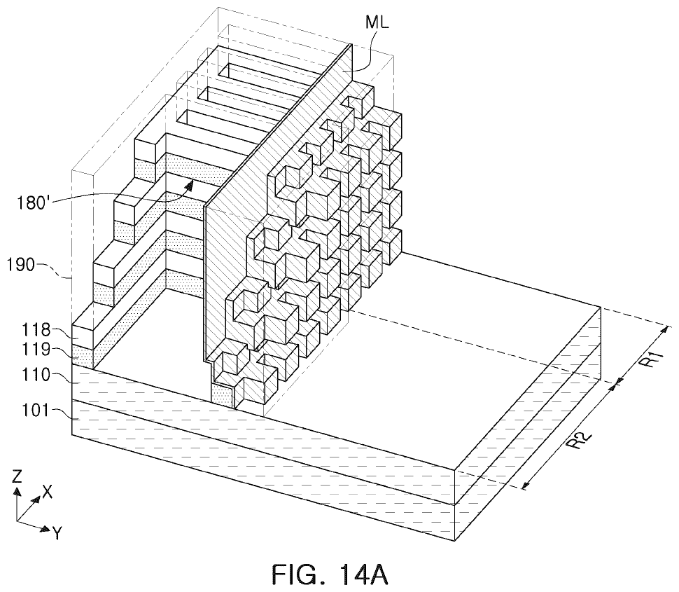

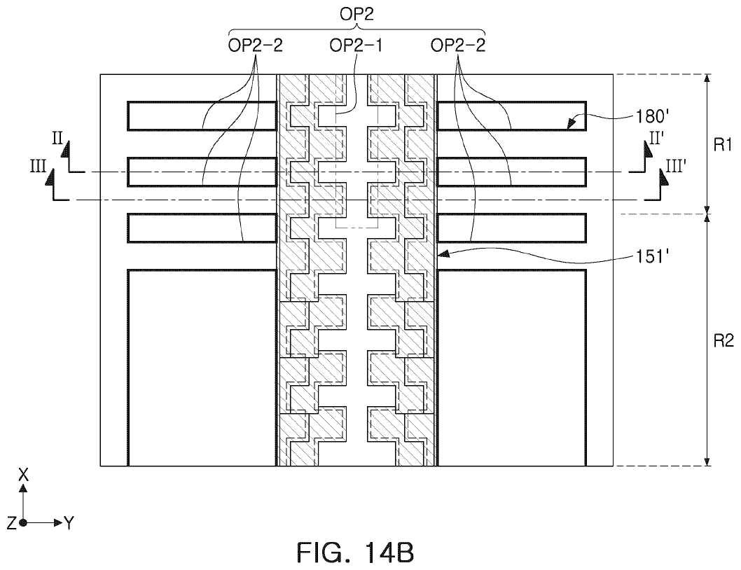

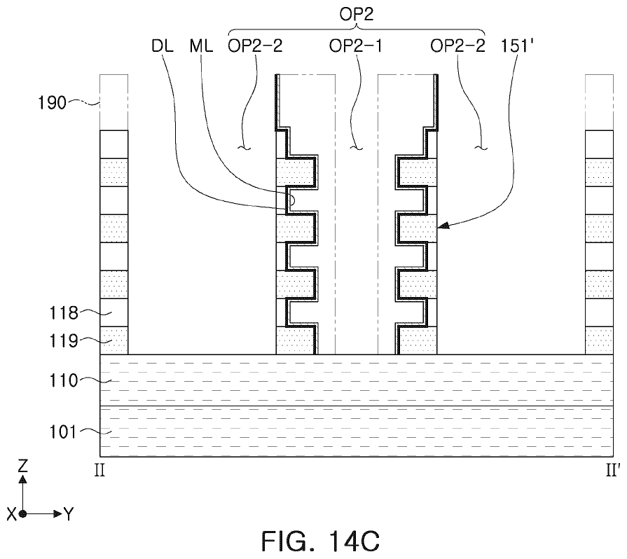

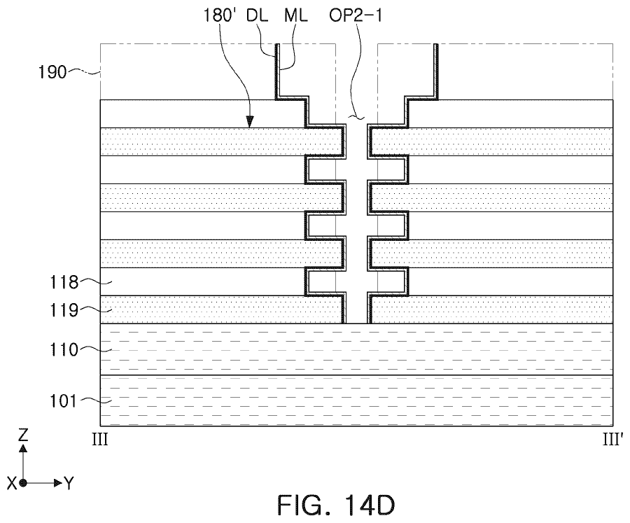

Referring to FIGS. 14A, 14B, 14C, and 14D, a second opening OP2 may be formed using a mask pattern, and a first preliminary source/drain region 151′ and sacrificial structures 180′ may be formed.

A second opening OP2 penetrating through the stack structure and exposing the lower structure 110 may be formed through an exposure and etching process using a mask pattern. The second opening may have a shape different from that of the first opening OP1.

In some example embodiments, the second opening OP2 may include a first opening region OP2-1 having a line shape, exposing a portion of the metal material layers ML disposed on the first region R1 without exposing a portion disposed on the second region R2. A width of the first opening region OP2-1 in the Y-direction may be smaller than the first width W1 and may be greater than the second width W2. The etching process may be of selectively removing the sacrificial layers 118, the semiconductor layers 119, and the gap-fill insulating layer 190 with respect to the metal material layer ML. Accordingly, at least a portion of the metal material layer ML surrounding the protrusions 119p on the first region R1 may be exposed. The length of the second source/drain region 152 (see FIG. 2A) formed through a subsequent process in the Y-direction may be determined by the width of the first opening region OP2-1 in the Y-direction.

In some example embodiments, the second opening OP2 may include second opening regions OP2-2 extending in the Y-direction and spaced apart from each other in the X-direction on the first region R1. Portions of the semiconductor layers 119 spaced apart from each other in the X-direction by the second opening regions OP2-2 may be referred to as sacrificial structures 180′. The sacrificial structures 180′ may be replaced with the data storage structure 180 through a subsequent process. The second opening regions OP2-2 may be spaced apart from the first opening region OP2-1, the metal material layer ML, and the dielectric material layer DL. At least a portion (e.g., portion other than the protrusions 119p) of the portions of the semiconductor layers 119 between the second opening regions OP2-2 and the first opening regions OP2-1 may be referred to as a first preliminary source/drain region 151′. The first preliminary source/drain region 151′ may extend in the X-direction between the sacrificial structures 180′ and the protrusions 119p.

In some example embodiments, the second opening regions OP2-2 may have a symmetrical shape from an axis of the first opening region OP2-1 in the X-direction.

In some example embodiments, the second opening regions OP2-2 may expose a portion of the dielectric material layer DL.

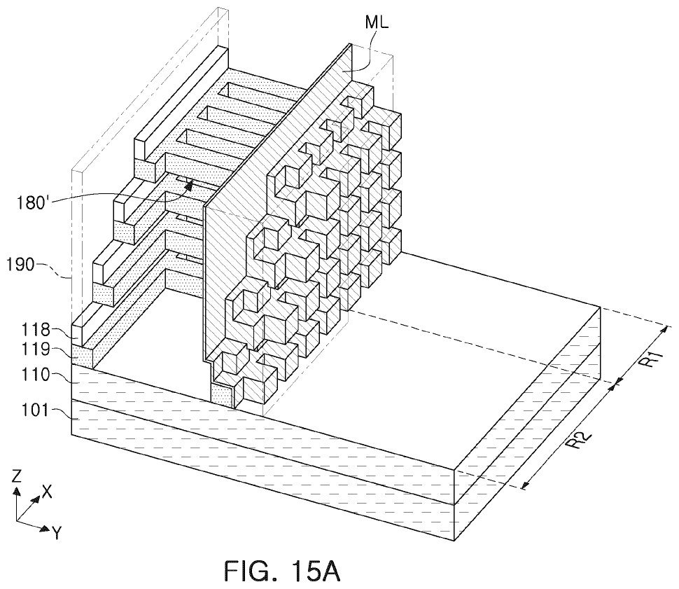

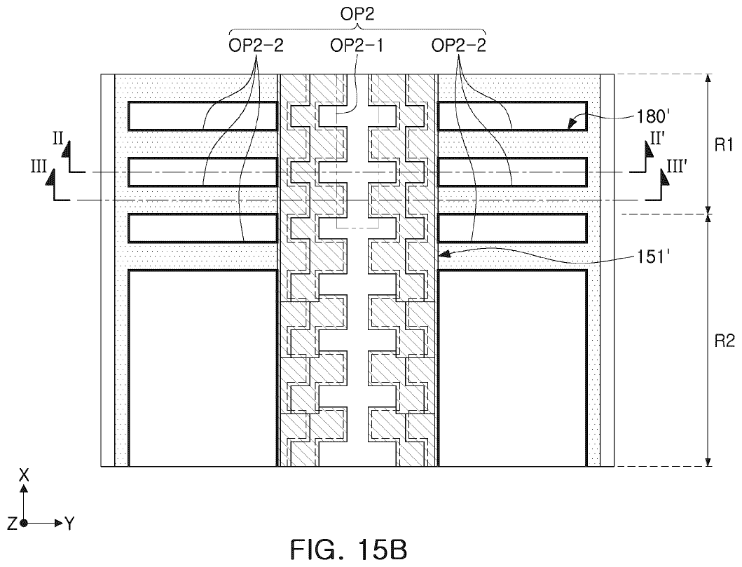

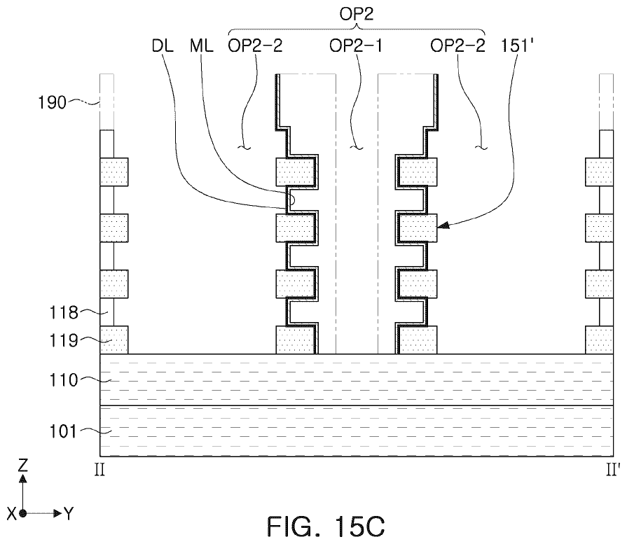

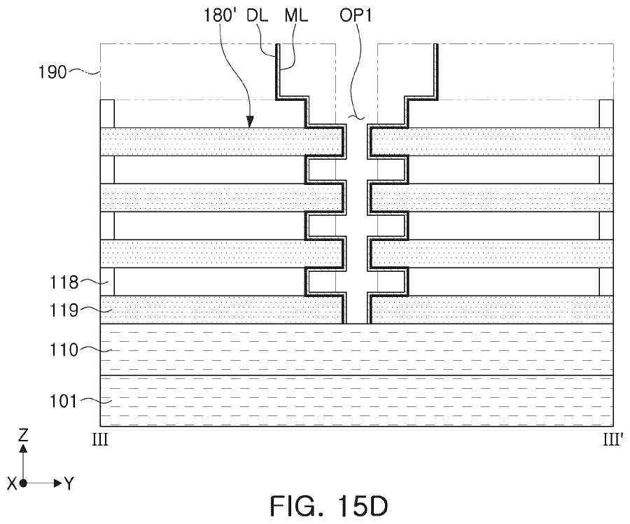

Referring to FIGS. 15A, 15B, 15C, and 15D, by removing a portion of the sacrificial layers 118 exposed through the second opening OP2, the four surfaces of the sacrificial structures 180′ may be exposed.

A wet etching process may be performed to selectively remove a portion of the sacrificial layers 118 exposed by the second opening regions OP2-2 of the second opening OP2 with respect to the semiconductor layers 119. The etching process may be performed to completely remove the sacrificial layers 118 between adjacent second opening regions OP2-2.

As the sacrificial layers 118 are removed by the etching process, the dielectric material layer DL disposed on the sidewall of the sacrificial layers 118 may be exposed.

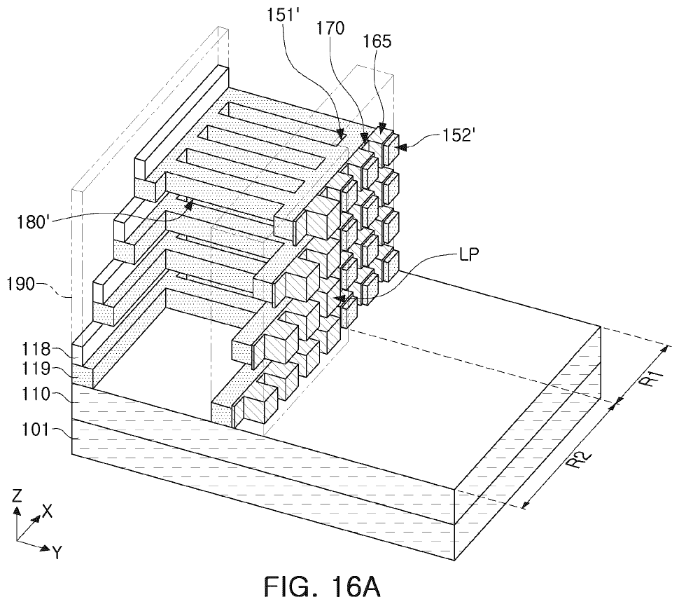

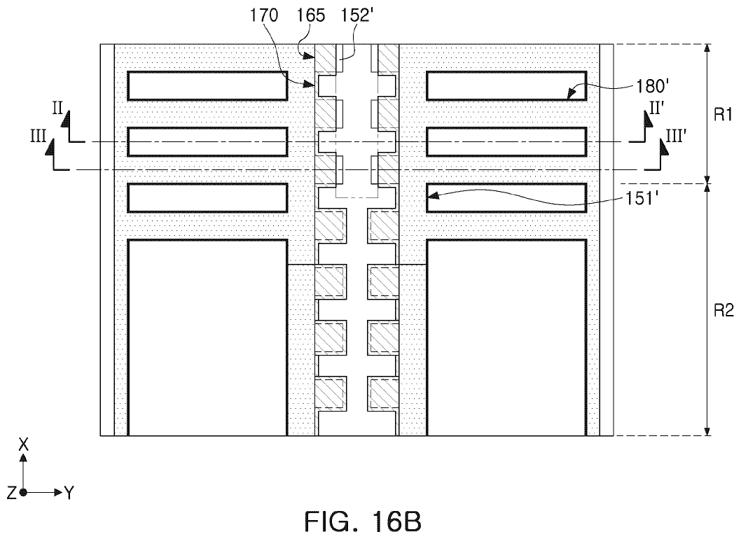

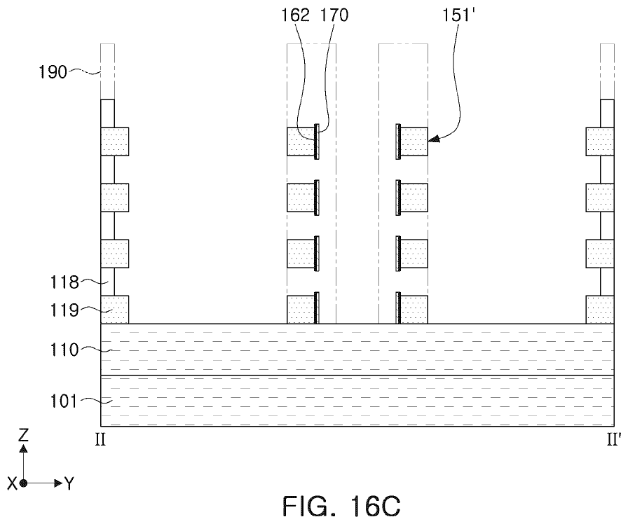

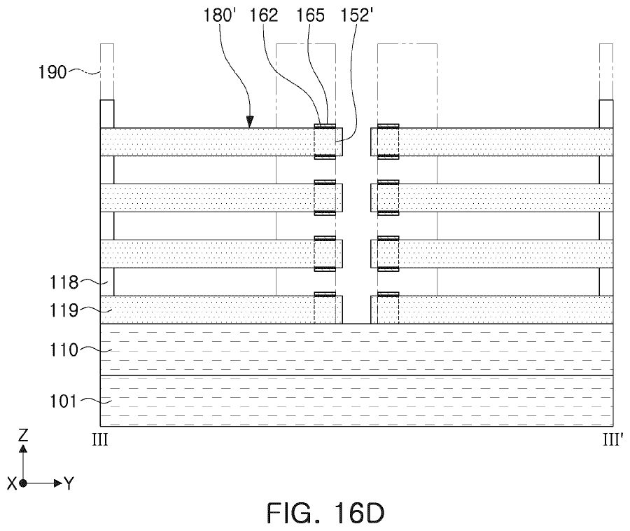

Referring to FIGS. 16A, 16B, 16C, and 16D, by performing an etching process, second preliminary source/drain regions 152′, a plurality of gate patterns 165, and a plurality of conductive line patterns 170 may be formed.

In the etching process through the first opening region OP2-1, by removing the dielectric material layer DL and the metal material layer ML surrounding one end of the protrusions 119p and exposing a portion of the protrusions 119p, the second preliminary source/drain regions 152′ may be formed. That is, the second preliminary source/drain regions 152′ may refer to a portion of the protrusions 119p exposed by the etching process. A length of the second source/drain region 152 (see FIG. 2A) in the Y-direction formed through a subsequent process may be determined depending on process conditions of the etching process.

In the etching process through the second opening regions OP2-2, by removing the dielectric material layer DL and the metal material layer ML exposed by the second opening regions OP2-2 and separating the metal material layer ML for each semiconductor layer 119, gate patterns 165 and conductive line patterns 170 may be formed. That is, the gate patterns 165 may refer to a portion of the metal material layer ML surrounding the protrusions 119p, and the conductive line patterns 170 may refer to a portion of the metal material layer ML disposed on the sidewall of the first preliminary source/drain region 151′ between the protrusions 119p. The gate patterns 165 and the conductive line patterns 170 may be integrally connected to each other.

In this process, the protrusions 119p disposed on the second region R2 and the metal material layer ML surrounding the protrusions 119p may not be exposed by the second opening OP2 such that the protrusions 119p may remain and may form the landing patterns LP without being removed.

In an example, the etching process may include a first etching process of selectively removing the dielectric material layer DL exposed through the second opening regions OP2-2, a second etching process of selectively removing the metal material layer ML exposed through the first and second opening regions OP2-1 and OP2-2, and a third etching process for selectively removing the dielectric material layer DL exposed through the first opening region OP2-1.

In another example, the etching process may include a first etching process of selectively removing the metal material layer ML exposed through the first opening region OP2-1, a second etching process of selectively removing the dielectric material layer DL exposed through the first and second opening regions OP2-1 and OP2-2, and a third etching process for selectively removing the metal material layer ML exposed through the second opening regions OP2-2.

In another example, the etching process may be performed as a single etching process to simultaneously remove the dielectric material layer DL and the metal material layer ML.

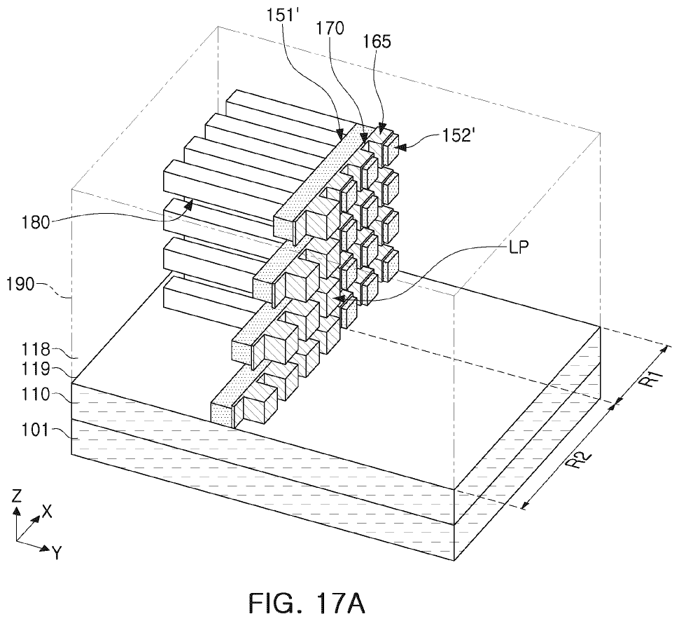

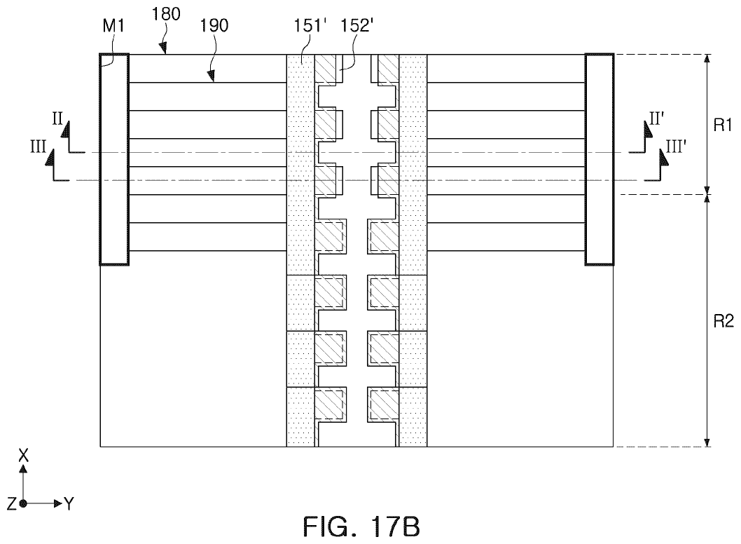

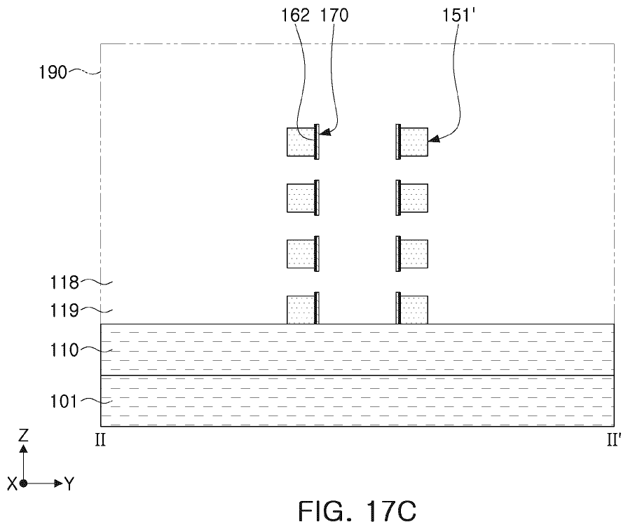

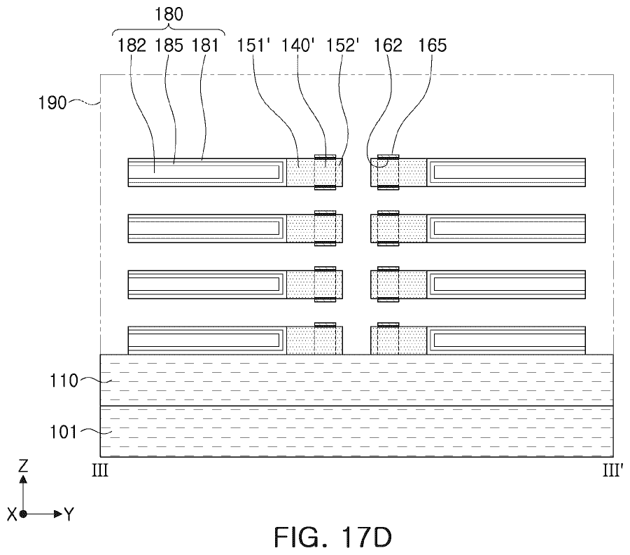

Referring to FIGS. 17A, 17B, 17C, and 17D, a third opening may be formed using the first mask pattern M1, the sacrificial structures 180′ may be removed, the data storage structure 180 may be formed, and a gap-fill insulating layer 190 may be additionally formed.

The third opening penetrating through the stack structure and exposing the lower structure 110 may be formed through an exposure and etching process using the first mask pattern M1. The third opening may have a trench shape extending in the X-direction from a position adjacent to an end of the second opening OP2. Sacrificial structures 180′ may be exposed through the third opening.

Tunnel portions may be formed by selectively removing the sacrificial structures 180′ exposed by the third opening, and a data storage structure 180 may be formed by forming a first electrode 181, a dielectric layer 185, and a second electrode 182 in order in the tunnel portions.

Thereafter, materials in the third opening may be removed through an etching process, and a gap-fill insulating layer 190 may be further formed. However, in this process, the etching process may not be performed.

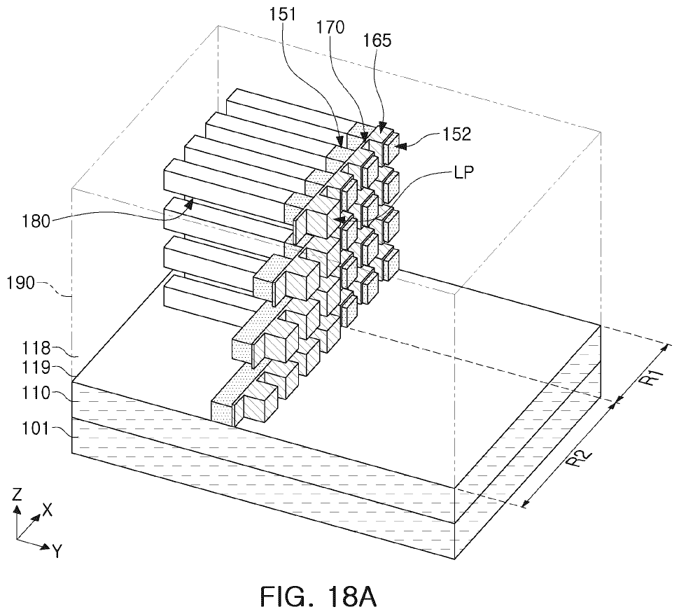

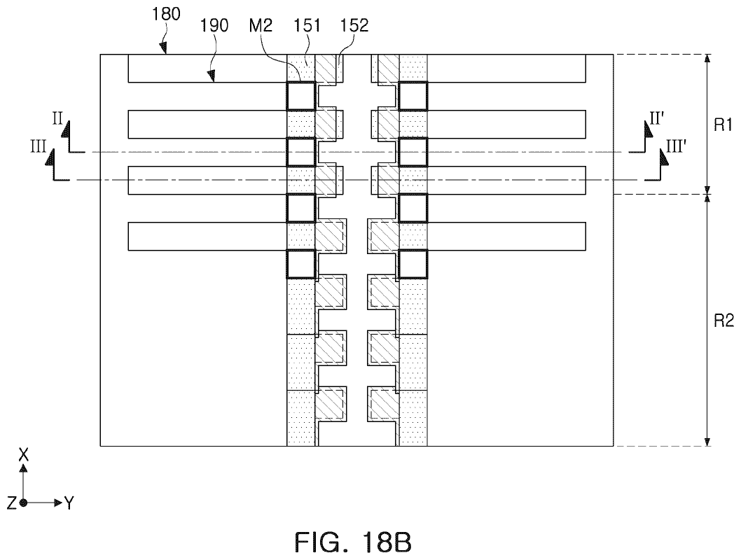

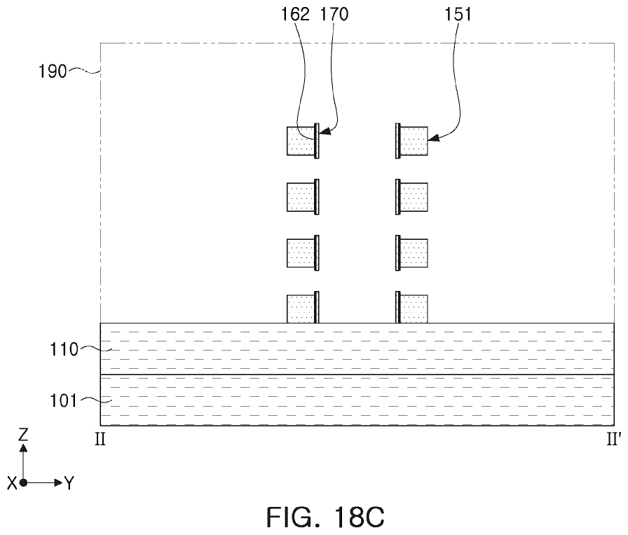

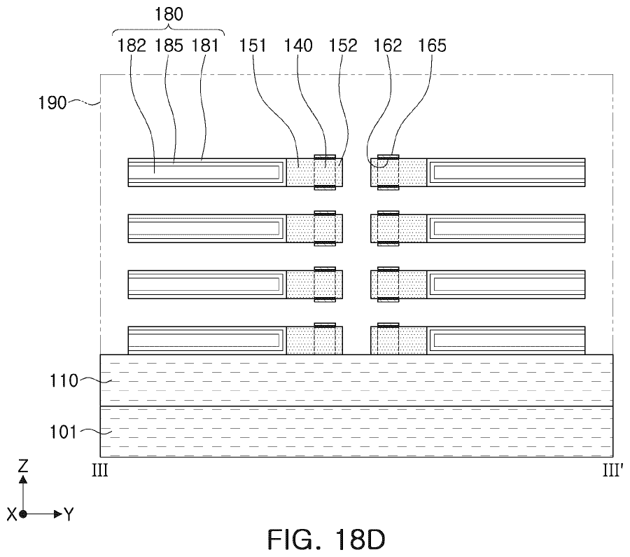

Referring to FIGS. 18A, 18B, 18C, and 18D, first and second source/drain regions 151 and 152 may be formed.

A fourth opening may be formed through a portion of the first preliminary source/drain regions 151′ using the second mask pattern M2. The first preliminary source/drain region 151′ extending in the X-direction may form a pattern structure including patterns spaced apart from each other in the X-direction by the fourth opening. First source/drain regions 151 may be formed by doping impurities to the pattern structure through the fourth opening.

The second source/drain regions 152 may be formed by forming an opening exposing the second preliminary source/drain regions 152′ and doping with impurities.

In some example embodiments, the order of forming the first and second source/drain regions 151 and 152 may be varied.

Accordingly, each of a plurality of structures LS including the semiconductor patterns 140, the first and second source/drain regions 151 and 152, the gate patterns 165, and the data storage structure 180 may be formed. The plurality of structures LS may be spaced apart from each other in the X and Z-directions. Accordingly, a semiconductor device having improved integration density may be provided.

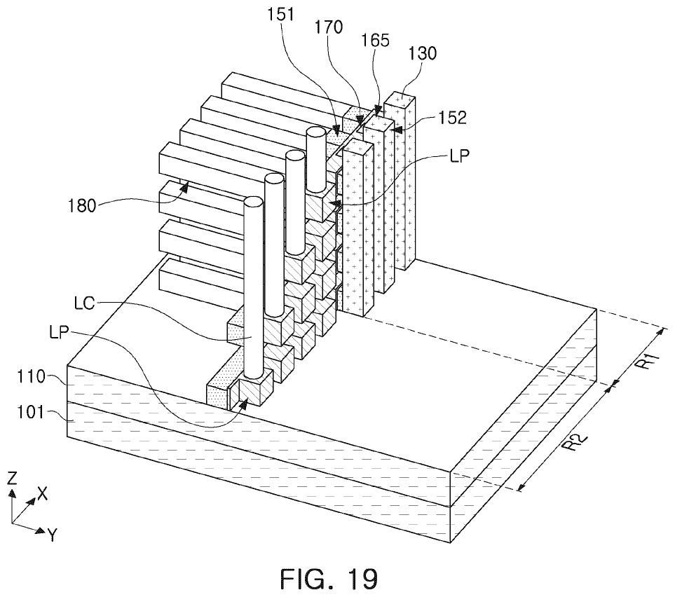

Referring to FIG. 19, a plurality of vertical conductive patterns 130 and landing contacts LC may be formed.

A plurality of vertical conductive patterns 130 may be formed by forming openings penetrating a region between the plurality of structures LS and spaced apart from each other in the X-direction, depositing a conductive material in the openings, and performing a planarization process.

Landing contacts LC may be formed, being in contact with the landing patterns LP penetrating the gap-fill insulating layer 190 and disposed on the second region R2.

Thereafter, by forming an upper wiring, the semiconductor device 100 in FIGS. 1A to 2B may be formed.

In some example embodiments, a manufacturing method may include manufacturing an electronic device to incorporate, and thus include, at least one semiconductor device according to any of the example embodiments, including for example the semiconductor device 100 in FIGS. 1A to 2B. Such an electronic device may include, for example, a smartphone, a computer, a laptop, a camera, any combination thereof, or the like. Such an electronic device may include, for example, one or more instances of processing circuitry, a processor (e.g., a central processing unit (CPU)), a memory (e.g., a DRAM device), any combination thereof, or the like. Such manufacturing of the electronic device may include manufacturing one or more components of the electronic device (e.g., a DRAM device) to include at least one semiconductor device according to any of the example embodiments, including for example the semiconductor device 100 in FIGS. 1A to 2B, and manufacturing the electronic device to include the one or more components.

As a result, an electronic device configured to have improved electrical properties and integration density (e.g., improved compactness, improved miniaturization, reduced form factor, etc.) may be manufactured based on being manufactured to include at least one semiconductor device according to any of the example embodiments.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

According to some of the example embodiments, by providing a plurality of semiconductor patterns spaced apart from each other horizontally and vertically and gate patterns surrounding each of the four surfaces of the plurality of semiconductor patterns, a semiconductor device having improved electrical properties and integration density may be provided. Additionally, by including such a semiconductor device in a manufactured electronic device, an electronic device having improved electrical properties and integration density may be provided.

While some example embodiments have been illustrated and described above, it will be configured as apparent to those skilled in the art that modifications and variations could be made without departing from the scope of the present inventive concepts as defined by the appended claims.

What is claimed is:

1. A semiconductor device, comprising:
a substrate;
a plurality of semiconductor patterns spaced apart from each other in a first horizontal direction on the substrate, wherein each of the plurality of semiconductor patterns has first side surfaces opposing each other in the first horizontal direction and second side surfaces opposing each other in a second horizontal direction, the first horizontal direction parallel to an upper surface of the substrate, the second horizontal direction parallel to the upper surface of the substrate and perpendicular to the first horizontal direction;
source/drain regions on the second side surfaces of each of the plurality of semiconductor patterns;
a plurality of gate patterns surrounding an upper surface, a lower surface, and the first side surfaces of each of the plurality of semiconductor patterns;
a plurality of conductive line patterns connecting the plurality of gate patterns to each other; and
data storage structures in parallel to the plurality of semiconductor patterns in the second horizontal direction.

2. The semiconductor device of claim 1, wherein each of the plurality of conductive line patterns extends in the first horizontal direction between adjacent gate patterns of the plurality of gate patterns.

3. The semiconductor device of claim 2,
wherein an upper surface of each of the plurality of conductive line patterns is coplanar with an upper surface of each of the plurality of gate patterns, and
wherein a lower surface of each of the plurality of conductive line patterns is coplanar with a lower surface of each of the plurality of gate patterns.

4. The semiconductor device of claim 1, wherein each of the plurality of conductive line patterns is integrally connected to each of the plurality of gate patterns.

5. The semiconductor device of claim 1, wherein the plurality of conductive line patterns include a material that is a same material as a material of the plurality of gate patterns.

6. The semiconductor device of claim 1, wherein each of the plurality of gate patterns has a substantially uniform thickness and surrounds a separate semiconductor pattern of the plurality of semiconductor patterns.

7. The semiconductor device of claim 6,
wherein a thickness of each of the plurality of conductive line patterns has a substantially same thickness as a thickness of each of the plurality of gate patterns, and
wherein the thickness of each of the plurality of conductive line patterns is defined in the second horizontal direction.

8. The semiconductor device of claim 1,
wherein the source/drain regions include a first source/drain region on one side of the plurality of semiconductor patterns and a second source/drain region on an opposite side opposing the one side of the plurality of semiconductor patterns, and
wherein a first length of the first source/drain region in the second horizontal direction is different from a second length of the second source/drain region in the second horizontal direction.

9. The semiconductor device of claim 8,
wherein the first source/drain region is between the plurality of semiconductor patterns and the data storage structures, and
wherein the first length is greater than the second length.

10. The semiconductor device of claim 8, wherein the first source/drain region includes a portion having a width in the first horizontal direction that increases in a direction from the data storage structures toward the plurality of semiconductor patterns.

11. The semiconductor device of claim 1, further comprising:
a plurality of vertical conductive patterns extending in a vertical direction perpendicular to the upper surface of the substrate and spaced apart from each other in the first horizontal direction on the substrate,
wherein the semiconductor patterns include
first semiconductor patterns on a first side of each of the plurality of vertical conductive patterns, and
second semiconductor patterns on a second side opposing the first side of each of the plurality of vertical conductive patterns.

12. The semiconductor device of claim 1, wherein a length of each of the plurality of semiconductor patterns in a vertical direction is a substantially same length as a length of each of the source/drain regions in the vertical direction.

13. A semiconductor device, comprising:
a substrate;
a plurality of horizontal structures and a plurality of interlayer insulating layers alternately stacked on the substrate; and
a vertical conductive pattern extending in a vertical direction perpendicular to an upper surface of the substrate on the substrate,
wherein each of the plurality of horizontal structures includes
a first structure on a first side of the vertical conductive pattern, and
a second structure spaced apart from the first structure and on a second side of the vertical conductive pattern opposing the first side,
wherein the vertical conductive pattern is electrically connected to the first structure and the second structure of each of the plurality of horizontal structures between the first structure and the second structure,
wherein each of the first structure and the second structure of each of the plurality of horizontal structures includes
a semiconductor pattern having first side surfaces opposing each other in a first horizontal direction and second side surfaces opposing each other in a second horizontal direction, the first horizontal direction parallel to the upper surface of the substrate, the second horizontal direction parallel to the upper surface of the substrate and perpendicular to the first horizontal direction,
source/drain regions including a first source/drain region on one side of the second side surfaces of the semiconductor pattern, and a second source/drain region on an opposite side opposing the one side of the second side surfaces of the semiconductor pattern and between the semiconductor pattern and the vertical conductive pattern,
a gate pattern surrounding an upper surface, a lower surface, and the first side surfaces of the semiconductor pattern, and
a data storage structure on a side surface of the first source/drain region of the source/drain regions.

14. The semiconductor device of claim 13,
wherein each of the plurality of interlayer insulating layers includes
a first portion vertically overlapping the gate pattern of at least one of the first structure or the second structure of at least one horizontal structure, and
a second portion vertically overlapping the source/drain regions and the data storage structure of the at least one of the first structure or the second structure of the at least one horizontal structure, and
wherein a thickness of the first portion in the vertical direction is smaller than a thickness of the second portion in the vertical direction.

15. The semiconductor device of claim 13,
wherein the vertical conductive pattern includes a plurality of vertical conductive patterns spaced apart from each other in the first horizontal direction,
wherein the first structure includes a plurality of first structures spaced apart from each other in the first horizontal direction,
wherein the second structure includes a plurality of second structures spaced apart from each other in the first horizontal direction, and
wherein each of the plurality of horizontal structures includes
first conductive line patterns connecting first gate patterns of the plurality of first structures to each other, and
second conductive line patterns connecting second gate patterns of the plurality of second structures to each other.

16. The semiconductor device of claim 15,
wherein each of the first conductive line patterns extends between adjacent first gate patterns of the first gate patterns in the first horizontal direction,
wherein each of the second conductive line patterns extends between adjacent second gate patterns of the second gate patterns in the first horizontal direction, and
wherein the first conductive line patterns are spaced apart from the second conductive line patterns.

17. The semiconductor device of claim 16,
wherein one side surface of each of the first conductive line patterns is coplanar with one side surface of each of the first gate patterns on a first plane, and
wherein one side surface of each of the second conductive line patterns is coplanar with one side surface of each of the second gate patterns on a second plane.

18. The semiconductor device of claim 13, wherein the first source/drain region has a recess portion in contact with the data storage structure and recessed by the data storage structure.

19. A semiconductor device, comprising:
a substrate;
a plurality of horizontal structures stacked and spaced apart from each other in a vertical direction perpendicular to an upper surface of the substrate;
a plurality of interlayer insulating layers alternately stacked with the plurality of horizontal structures; and
a plurality of vertical conductive patterns extending in the vertical direction based on penetrating through the plurality of horizontal structures and the plurality of interlayer insulating layers, and spaced apart from each other in a first horizontal direction, the first horizontal direction parallel to the upper surface of the substrate,
wherein each of the plurality of horizontal structures includes
first structures spaced apart from each other in the first horizontal direction on a first side of the plurality of vertical conductive patterns,
first conductive line patterns connecting the first structures to each other,
second structures spaced apart from each other in the first horizontal direction on a second side of the plurality of vertical conductive patterns opposing the first side, and
second conductive line patterns connecting the second structures to each other,
wherein each of the first structures and the second structures includes
a semiconductor pattern having first side surfaces opposing each other in the first horizontal direction and second side surfaces opposing each other in a second horizontal direction parallel to the upper surface of the substrate and perpendicular to the first horizontal direction;
source/drain regions on the second side surfaces of the semiconductor pattern;
a gate pattern surrounding an upper surface, a lower surface, and the first side surfaces of the semiconductor pattern; and
a data storage structure in parallel to the semiconductor pattern in the second horizontal direction on one side of the source/drain regions.

20. The semiconductor device of claim 19,
wherein the first conductive line patterns are integrally connected to gate patterns of the first structures, and
wherein the second conductive line patterns are integrally connected to gate patterns of the second structures.
